(19) United States
(12) Patent Application Publication
(10) Pub. No.: US 2026/0080913 A1
(43) Pub. Date: Mar. 19, 2026

(54) SEMICONDUCTOR MEMORY DEVICE

(71) Applicant: Kioxia Corporation, Tokyo (JP)

(72) Inventors: Ken OSUMI, Yokkaichi (JP); Hisashi KATO, Yokkaichi (JP); Kazutaka SUZUKI, Kuwana (JP); Shunsuke AITA, Kuwana (JP)

(73) Assignee: Kioxia Corporation, Tokyo (JP)

(21) Appl. No.: 19/073,130

(22) Filed: Mar. 7, 2025

(30) Foreign Application Priority Data
Sep. 18, 2024 (JP) 2024-160652

(51) Int. Cl. G11C 5/06; G11C 16/04; H10B 41/10; H10B 41/27; H10B 43/10; H10B 43/27

(52) U.S. Cl. CPC G11C 5/063; G11C 16/0483; H10B 41/10; H10B 41/27; H10B 43/10; H10B 43/27

(57) ABSTRACT

A semiconductor memory device comprises: first to third layers; first and second semiconductor layers opposed to the first to third layers; and first to third electrodes connected to the first to third layers. The first layer includes: a first conductive layer opposed to the first semiconductor layer and connected to the first electrode; a second conductive layer opposed to the second semiconductor layer; and an intermediate layer continuously formed in a region between the second electrode and the third electrode without being electrically connected to the first conductive layer or the second conductive layer. Each of the second layer and the third layer includes a third conductive layer that is continuously formed in a region between the first semiconductor layer and the second semiconductor layer and opposed to the first and second semiconductor layers.

### CROSS-REFERENCE TO RELATED APPLICATIONS

This application is based upon and claims the benefit of Japanese Patent Application No. 2024-160652, filed on Sep. 18, 2024, the entire contents of which are incorporated herein by reference.

### BACKGROUND

### Field

Embodiments described herein relate generally to a semiconductor memory device.

### Description of the Related Art

There has been known a semiconductor memory device that includes a substrate, a plurality of conductive layers stacked in a direction intersecting with a surface of this substrate, a semiconductor layer opposed to these plurality of conductive layers, and a gate insulating layer disposed between the conductive layers and the semiconductor layer.

The gate insulating layer includes a memory portion configured to be able to store data. The memory portion is, for example, an insulating electric charge accumulating layer of silicon nitride (SiN) or the like and a conductive electric charge accumulating layer, such as a floating gate.

### BRIEF DESCRIPTION OF THE DRAWINGS

FIG. 1 is a schematic circuit diagram illustrating a part of a configuration of a semiconductor memory device according to a first embodiment;

FIG. 2 is a schematic plan view of the semiconductor memory device;

FIG. 3 is a schematic enlarged view of a part indicated by A in FIG. 2;

FIG. 4 is a schematic enlarged view of a memory hole region R_{MH};

FIG. 5 is a schematic cross-sectional view of the structure illustrated in FIG. 4 taken along the line D-D′ and viewed along a direction of arrows;

FIG. 6 is a schematic enlarged view of a part indicated by E in FIG. 5;

FIG. 7 is a schematic cross-sectional view for describing the structure of a part indicated by A2 in FIG. 2;

FIG. 8 is a schematic cross-sectional view of a part indicated by A in FIG. 2;

FIG. 9 is a schematic cross-sectional view for describing a manufacturing method 1 of the semiconductor memory device according to the first embodiment;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing a manufacturing method 2 of the semiconductor memory device according to the first embodiment;

FIG. 15 is a schematic cross-sectional view for describing the manufacturing method;

FIG. 16 is a schematic cross-sectional view for describing the manufacturing method;

FIG. 17 is a schematic cross-sectional view for describing a manufacturing method 3 of the semiconductor memory device according to the first embodiment;

FIG. 18 is a schematic cross-sectional view for describing the manufacturing method;

FIG. 19 is a schematic cross-sectional view for describing the manufacturing method;

FIG. 20 is a schematic plan view illustrating a part of a configuration of a modification 1 of the first embodiment;

FIG. 21 is a schematic plan view illustrating a part of a configuration of a modification 2 of the first embodiment;

FIG. 22 is a schematic cross-sectional view illustrating a part of the configuration of the modification;

FIG. 23 is a schematic plan view illustrating a part of a configuration of a semiconductor memory device according to a second embodiment;

FIG. 24 is a schematic cross-sectional view illustrating a part of the configuration of the semiconductor memory device;

FIG. 25 is a schematic cross-sectional view illustrating a part of the configuration of the semiconductor memory device;

FIG. 26 is a schematic plan view for describing a method for manufacturing the semiconductor memory device according to the second embodiment;

FIG. 27 is a schematic cross-sectional view for describing the manufacturing method;

FIG. 28 is a schematic plan view for describing the manufacturing method;

FIG. 29 is a schematic cross-sectional view for describing the manufacturing method;

FIG. 30 is a schematic plan view for describing the manufacturing method;

FIG. 31 is a schematic cross-sectional view for describing the manufacturing method;

FIG. 32 is a schematic plan view for describing the manufacturing method;

FIG. 33 is a schematic cross-sectional view for describing the manufacturing method;

FIG. 34 is a schematic cross-sectional view for describing the manufacturing method;

FIG. 35 is a schematic plan view for describing the manufacturing method;

FIG. 36 is a schematic cross-sectional view for describing the manufacturing method;

FIG. 37 is a schematic plan view for describing the manufacturing method;

FIG. 38 is a schematic cross-sectional view for describing the manufacturing method;

FIG. 39 is a schematic plan view for describing the manufacturing method;

FIG. 40 is a schematic cross-sectional view for describing the manufacturing method;

FIG. 41 is a schematic plan view for describing the manufacturing method;

FIG. 42 is a schematic cross-sectional view for describing the manufacturing method;

FIG. 43 is a schematic cross-sectional view for describing the manufacturing method;

FIG. 44 is a schematic plan view for describing the manufacturing method;

FIG. 45 is a schematic cross-sectional view for describing the manufacturing method;

FIG. 46 is a schematic cross-sectional view for describing the manufacturing method;

FIG. 47 is a schematic plan view illustrating a part of a configuration of a semiconductor memory device according to a third embodiment;

FIG. 48 is a schematic cross-sectional view illustrating a part of the configuration of the semiconductor memory device;

FIG. 49 is a schematic cross-sectional view illustrating a part of the configuration of the semiconductor memory device;

FIG. 50 is a schematic cross-sectional view illustrating a part of the configuration of the semiconductor memory device;

FIG. 51 is a schematic cross-sectional view illustrating a part of the configuration of the semiconductor memory device;

FIG. 52 is a schematic cross-sectional view illustrating a part of the configuration of the semiconductor memory device;

FIG. 53 is a schematic cross-sectional view for describing a method for manufacturing the semiconductor memory device according to the third embodiment;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic cross-sectional view for describing the manufacturing method;

FIG. 59 is a schematic cross-sectional view for describing the manufacturing method;

FIG. 60 is a schematic cross-sectional view for describing the manufacturing method;

FIG. 61 is a schematic cross-sectional view for describing the manufacturing method;

FIG. 62 is a schematic cross-sectional view for describing the manufacturing method;

FIG. 63 is a schematic cross-sectional view for describing the manufacturing method;

FIG. 64 is a schematic cross-sectional view for describing the manufacturing method;

FIG. 65 is a schematic cross-sectional view for describing the manufacturing method;

FIG. 66 is a schematic cross-sectional view for describing the manufacturing method;

FIG. 67 is a schematic cross-sectional view for describing the manufacturing method;

FIG. 68 is a schematic cross-sectional view for describing the manufacturing method; and

FIG. 69 is a schematic cross-sectional view illustrating a part of a configuration of a modification of the third embodiment.

### DETAILED DESCRIPTION

A semiconductor memory device according to one embodiment comprises: a substrate; a first layer disposed to be spaced from the substrate in a first direction intersecting with a surface of the substrate; a second layer disposed on one side in the first direction with respect to the first layer; a third layer disposed on one side in the first direction with respect to the second layer; a first semiconductor layer and a second semiconductor layer extending in the first direction and opposed to the first layer, the second layer, and the third layer; a first electrode extending in the first direction and connected to the first layer; a second electrode extending in the first direction and having an outer peripheral surface surrounded by the first layer and an end portion on one side in the first direction connected to the second layer; a third electrode extending in the first direction and having an outer peripheral surface surrounded by the first layer and the second layer, and an end portion on one side in the first direction connected to the third layer; and a first insulating layer extending in the first direction and a second direction intersecting with the first direction, the first insulating layer separating a part of the first layer without separating the second layer or the third layer. The second electrode and the third electrode are farther from the first semiconductor layer in the second direction than the first electrode. The second semiconductor layer is farther from the first semiconductor layer in the second direction than the second electrode and the third electrode. The first layer includes: a first conductive layer opposed to the first semiconductor layer and connected to the first electrode; a second conductive layer opposed to the second semiconductor layer; and an intermediate layer continuously formed in a region between the second electrode and the third electrode without being electrically connected to the first conductive layer or the second conductive layer. Each of the second layer and the third layer includes a third conductive layer that is continuously formed in a region between the first semiconductor layer and the second semiconductor layer and opposed to the first semiconductor layer and the second semiconductor layer.

Next, semiconductor memory devices according to embodiments are described in detail with reference to the drawings. The following embodiments are only examples and not described for the purpose of limiting the present invention. The following drawings are schematic, and for convenience of description, a part of a configuration and the like is sometimes omitted. Parts common in a plurality of embodiments are attached by same reference numerals, and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion on the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

### First Embodiment

### Configuration

### Circuit Configuration of Memory Die MD

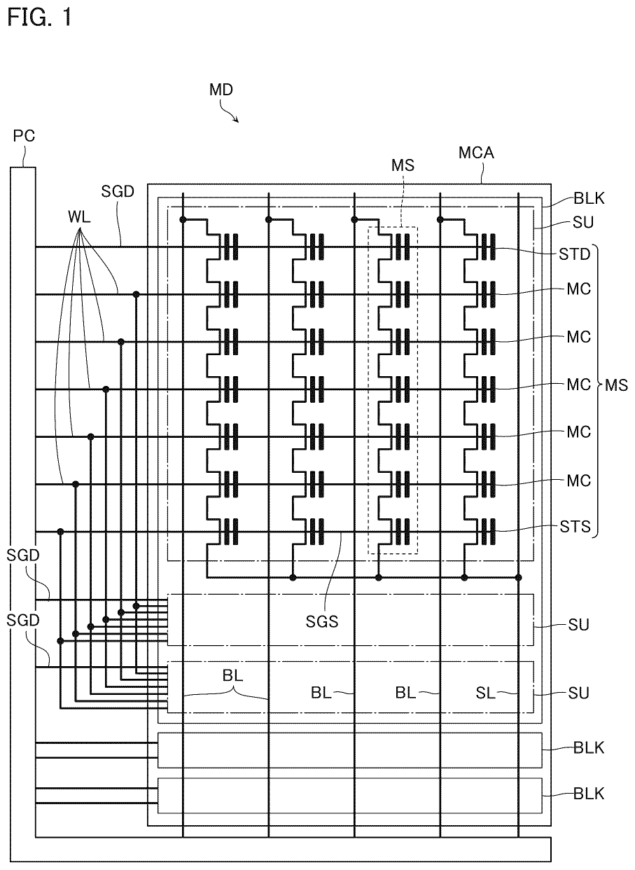

FIG. 1 is a schematic circuit diagram illustrating a part of a configuration of a memory die MD. As illustrated in FIG. 1, the memory die MD includes a memory cell array MCA and a peripheral circuit PC. The memory cell array MCA includes a plurality of memory blocks BLK. These plurality of memory blocks BLK each include a plurality of string units SU. These plurality of string units SU each include a plurality of memory strings MS. Each of these plurality of memory strings MS has one end connected to the peripheral circuit PC via a bit line BL. In addition, each of these plurality of memory strings MS has the other end connected to the peripheral circuit PC via a common source line SL.

The memory string MS includes a drain-side select transistor STD, a plurality of memory cells MC (memory transistors), and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as select transistors (STD, STS).

The memory cell MC is a field-effect type transistor. The memory cell MC includes a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores one bit or a plurality of bits of data. Respective word lines WL are connected to the gate electrodes of the plurality of memory cells MC corresponding to one memory string MS. Each of these word lines WL is connected in common to all of the memory strings MS in one memory block BLK.

The select transistors (STD, STS) are field-effect type transistors. The select transistors (STD, STS) each include a semiconductor layer, a gate insulating film, and a gate electrode. The semiconductor layer functions as a channel region. The gate insulating film may include an electric charge accumulating layer. Select gate lines (SGD, SGS) are connected to the gate electrodes of the select transistors (STD, STS), respectively. One drain-side select gate line SGD is connected in common to all of the memory strings MS in one string unit SU. One source-side select gate line SGS is connected in common to all of the memory strings MS in one memory block BLK.

### Structure of Memory Die MD

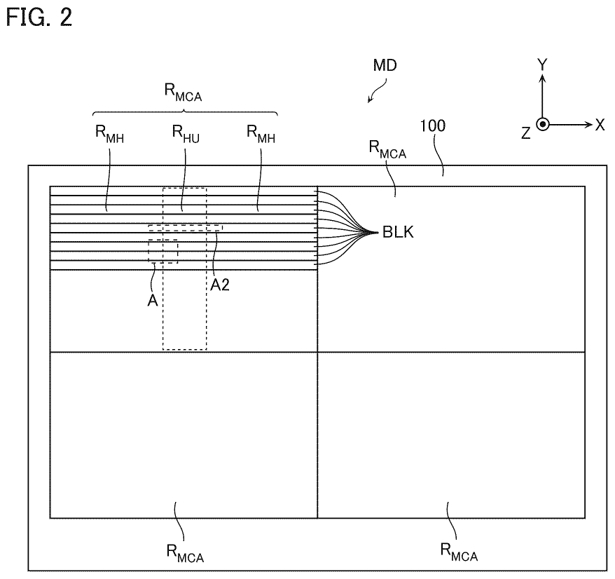

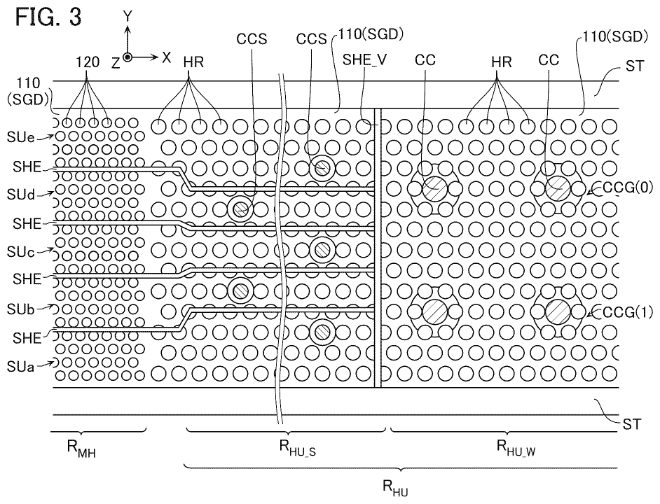

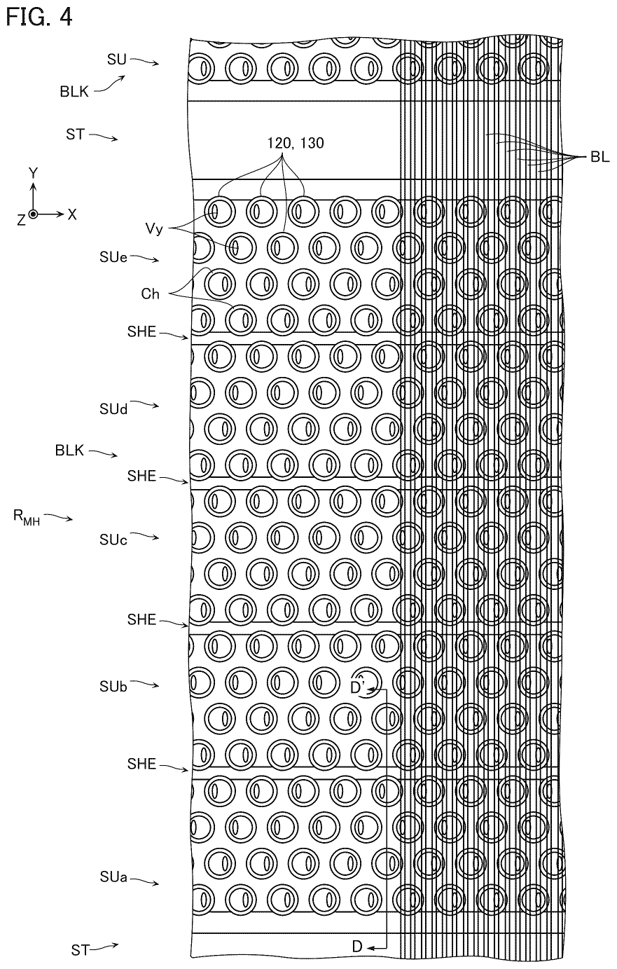

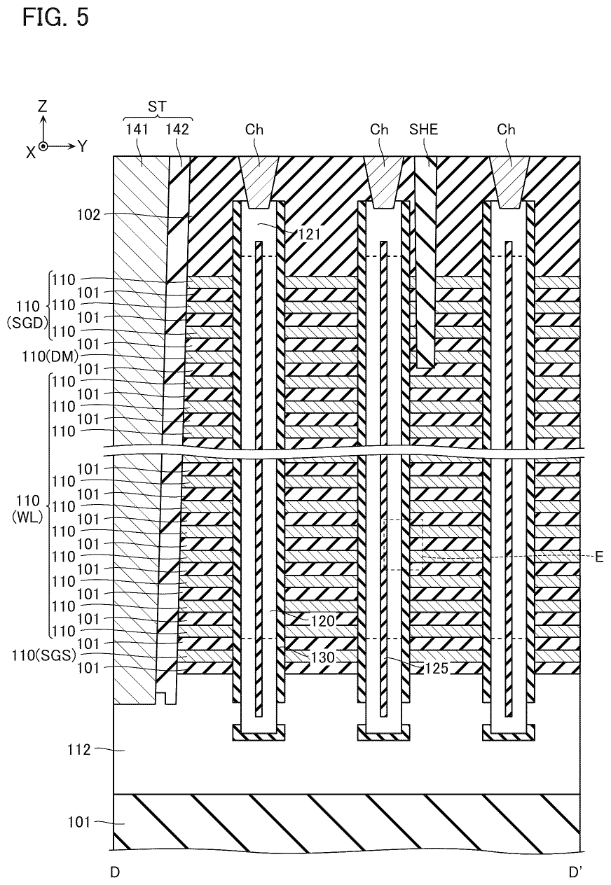

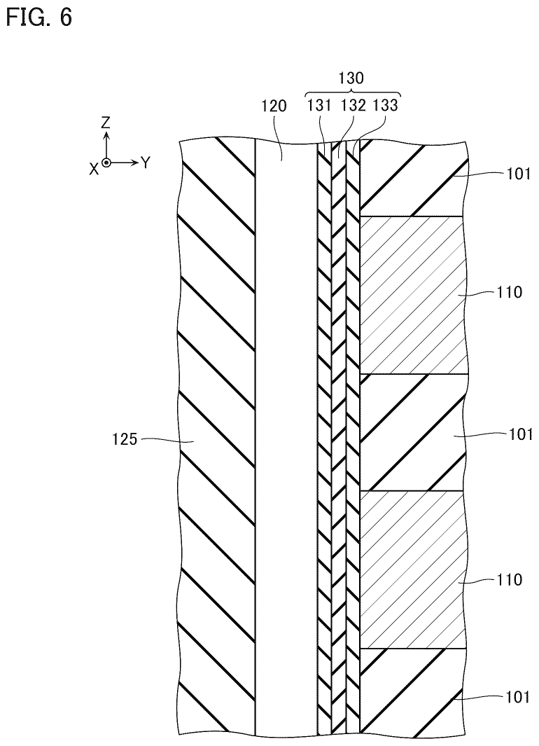

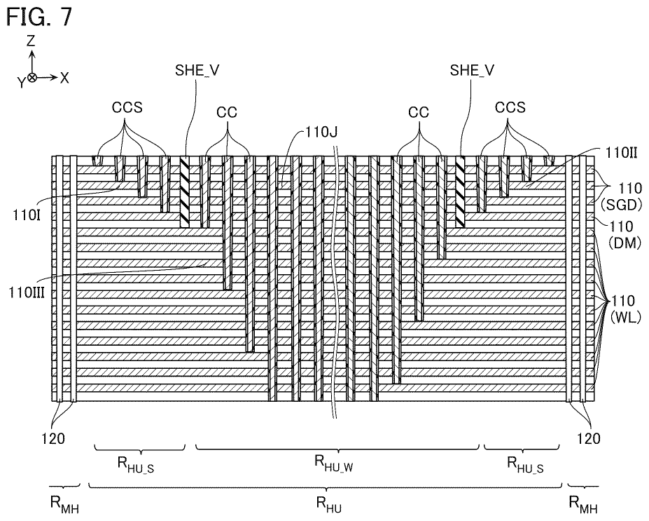

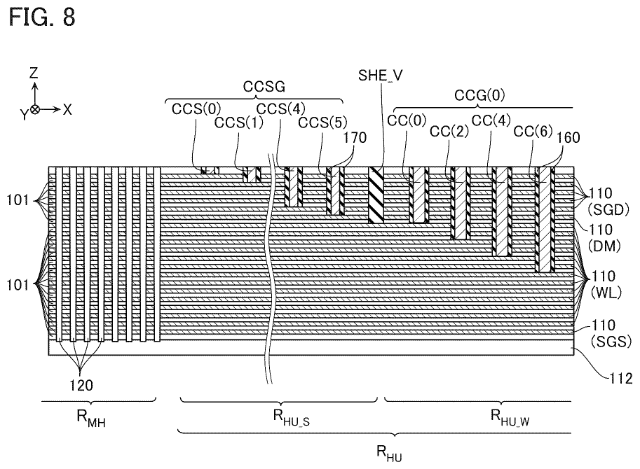

FIG. 2 is a schematic plan view of the memory die MD. FIG. 3 is a schematic enlarged view of a part indicated by A in FIG. 2. FIG. 4 is a schematic enlarged view of a memory hole region R_{MH}. FIG. 5 is a schematic cross-sectional view of the structure illustrated in FIG. 4 taken along the line D-D′ and viewed along a direction of arrows. FIG. 6 is a schematic enlarged view of a part indicated by E in FIG. 5. FIG. 7 is a schematic cross-sectional view for describing the structure of a part indicated by A2 in FIG. 2. FIG. 8 is a schematic cross-sectional view of a part indicated by A in FIG. 2.

For example, as illustrated in FIG. 2, the memory die MD includes a semiconductor substrate 100. For example, the semiconductor substrate 100 is made of P-type silicon (Si) containing P-type impurities, such as boron (B). On a surface of the semiconductor substrate 100, an N-type well region containing N-type impurities, such as phosphorus (P), a P-type well region containing P-type impurities, such as boron (B), a semiconductor substrate region in which the N-type well region or the P-type well region is not disposed, and an insulating region are disposed.

In addition, the memory die MD includes four memory cell array regions R_{MCA} arranged in the X-direction and the Y-direction. The memory cell array region R_{MCA} includes two memory hole regions R_{MH} arranged in the X-direction and a hook-up region R_{HU} disposed between these memory hole regions R_{MH}. Also, a plurality of memory blocks BLK arranged in the Y-direction are disposed in the memory cell array region R_{MCA}. For example, as illustrated in FIG. 4, an inter-block structure ST of silicon oxide (SiO₂) or the like is disposed between the two memory blocks BLK mutually adjacent in the Y-direction.

The memory block BLK includes a plurality of string units SU arranged in the Y-direction. In FIG. 3 and FIG. 4, five string units SU arranged in the Y-direction are denoted as string units SUa, SUb, SUc, SUd, SUe from a negative side in the Y-direction. An inter-string unit insulating layer SHE of silicon oxide (SiO₂) or the like is disposed between two string units SU mutually adjacent in the Y-direction.

For example, as illustrated in FIG. 5 to FIG. 8, the memory block BLK includes a plurality of conductive layers 110 arranged in the Z-direction. Between the plurality of conductive layers 110 arranged in the Z-direction, insulating layers 101 of silicon oxide (SiO₂) or the like are disposed.

The conductive layer 110 is an approximately plate-shaped conductive layer extending in the X-direction and the Y-direction. For example, as illustrated in FIG. 7, the conductive layer 110 is disposed across the two memory hole regions R_{MH} arranged in the X-direction and the hook-up region R_{HU} between the memory hole regions R_{MH}.

The conductive layers 110 may include, for example, a stacked film of a barrier conductive film of titanium nitride (TiN) or the like and a metal film of tungsten (W) or the like. Further, the conductive layers 110 may include, for example, polycrystalline silicon containing impurities, such as phosphorus (P) or boron (B). The conductive layers 110 function as the gate electrodes of the memory cells MC and the word lines WL, or the gate electrodes of the select transistors (STD, STS) and the select gate lines (SGD, SGS).

The memory hole region R_{MH} of the memory block BLK includes, for example, as illustrated in FIG. 5, a plurality of semiconductor layers 120 extending in the Z-direction and a plurality of gate insulating films 130 disposed between the plurality of conductive layers 110 and the respective plurality of semiconductor layers 120.

Of the plurality of conductive layers 110, one or a plurality of conductive layers 110 positioned at an uppermost layer may be referred to as conductive layers 110 (SGD) in the following description (FIG. 7, FIG. 8). The conductive layers 110 (SGD) function as the drain-side select gate lines SGD and the gate electrodes of the plurality of drain-side select transistors STD (FIG. 1) connected to the drain-side select gate lines SGD in the memory hole regions R_{MH} and a part (region R_{HU_S}) of the hook-up region R_{HU}. In the memory hole regions R_{MH} and the part (region R_{HU_S}) of the hook-up region R_{HU}, an inter-string unit insulating layer SHE (FIG. 5) is disposed between two conductive layers 110 (SGD) mutually adjacent in the Y-direction, and the conductive layers 110 (SGD) in these regions are each electrically independent for each string unit SU.

In addition, a plurality of conductive layers 110 positioned below the conductive layers 110 (SGD) may be referred to as conductive layers 110 (WL) in the following description (FIG. 7, FIG. 8). The conductive layers 110 (WL) function as the word lines WL (FIG. 1) and the gate electrodes of the plurality of memory cells MC (FIG. 1) connected to the word lines WL. The plurality of conductive layers 110 (WL) are each electrically independent for each memory block BLK.

In addition, one or a plurality of conductive layers 110 positioned below the conductive layers 110 (WL) may be referred to as conductive layers 110 (SGS) in the following description (FIG. 8). The conductive layers 110 (SGS) function as the source-side select gate lines SGS (FIG. 1) and the gate electrodes of the plurality of source-side select transistors STS connected to the source-side select gate lines SGS. The conductive layers 110 (SGS) are electrically independent for each memory block BLK.

The inter-string unit insulating layer SHE extends, for example, in the X-direction and the Z-direction. For example, as illustrated in FIG. 3 and FIG. 4, the inter-string unit insulating layer SHE is disposed along an extending direction of the inter-block structures ST. Further, for example, as illustrated in FIG. 5, a lower surface of the inter-string unit insulating layer SHE is disposed between the conductive layer 110 (SGD) positioned at a lowermost layer and the conductive layer 110 (WL) positioned at an uppermost layer. The inter-string unit insulating layer SHE separates the conductive layers 110 (SGD) in the Y-direction and does not separate the conductive layers 110 (WL).

Of the plurality of conductive layers 110, a conductive layer 110 (DM) functioning as one or a plurality of dummies may be disposed between the lowermost conductive layer 110 (SGD) and the uppermost conductive layer 110 (WL) (FIG. 5 to FIG. 8). The inter-string unit insulating layer SHE may separate the conductive layer 110 (DM) in the Y-direction or need not separate the conductive layer 110 (DM).

The conductive layer 110 (SGD) has a width in the Y-direction smaller than a width in the Y-direction of the conductive layer 110 (WL). For example, in the example of FIG. 3 and FIG. 4, five conductive layers 110 (SGD) arranged in the Y-direction and four inter-string unit insulating layers SHE arranged in the Y-direction are disposed corresponding to one conductive layer 110 (WL). In the illustrated example, the width in the Y-direction of the conductive layer 110 (SGD) is smaller than ⅕ of the width in the Y-direction of the conductive layer 110 (WL).

A semiconductor layer 112 is disposed below the conductive layers 110 (FIG. 5). The semiconductor layer 112 may include, for example, polycrystalline silicon containing impurities, such as phosphorus (P) or boron (B). An insulating layer 101 of silicon oxide (SiO₂) or the like is disposed between the semiconductor layer 112 and the conductive layers 110. The semiconductor layer 112 functions as a part of the source line SL.

For example, as illustrated in FIG. 4, the semiconductor layers 120 are arranged in the X-direction and the Y-direction in a predetermined pattern. The semiconductor layers 120 function as channel regions of the plurality of memory cells MC and the select transistors (STD, STS). The semiconductor layer 120 includes, for example, polycrystalline silicon (Si) or the like. For example, as illustrated in FIG. 5, the semiconductor layer 120 has an approximately cylindrical shape and has an insulating layer 125 of silicon oxide (SiO₂) or the like disposed in a center portion. Outer peripheral surfaces of the semiconductor layers 120 are each surrounded by the conductive layers 110 and opposed to the conductive layers 110.

The semiconductor layer 120 has an upper end portion where an impurity region 121 containing N-type impurities, such as phosphorus (P), is disposed. In the example of FIG. 5, a boundary line between the upper end portion of the semiconductor layer 120 and a lower end portion of the impurity region 121 is indicated by a dashed line. The impurity region 121 is connected to the bit line BL via a contact Ch and a contact Vy (FIG. 4).

A lower end portion of the semiconductor layer 120 is connected to the semiconductor layer 112.

The gate insulating film 130 has an approximately cylindrical shape that covers the outer peripheral surface of the semiconductor layer 120. For example, as illustrated in FIG. 6, the gate insulating film 130 includes a tunnel insulating film 131, an electric charge accumulating film 132, and a block insulating film 133, which are stacked between the semiconductor layer 120 and the conductive layers 110. The tunnel insulating film 131 and the block insulating film 133 are, for example, insulating films of silicon oxide (SiO₂) or the like. The electric charge accumulating film 132 is, for example, a film of silicon nitride (SiN) or the like capable of accumulating electric charge. The tunnel insulating film 131, the electric charge accumulating film 132, and the block insulating film 133, which have approximately cylindrical shapes, extend in the Z-direction along the outer peripheral surface of the semiconductor layer 120 excluding a contact portion of the semiconductor layer 120 and the semiconductor layer 112.

FIG. 6 illustrates an example in which the gate insulating film 130 includes the electric charge accumulating film 132 of silicon nitride or the like. However, the gate insulating film 130 may, for example, include a floating gate of, for example, polycrystalline silicon containing N-type or P-type impurities.

For example, as illustrated in FIG. 3, the inter-block structure ST extends in the X-direction across the two memory hole regions R_{MH} arranged in the X-direction and the hook-up region R_{HU} between the memory hole regions R_{MH}. Additionally, for example, as illustrated in FIG. 5, the inter-block structure ST extends in the Z-direction so as to separate the plurality of insulating layers 101 and the plurality of conductive layers 110 in the Y-direction. Side surfaces on a positive side in the Y-direction and the negative side in the Y-direction of the conductive layers 110 (WL) are in contact with the inter-block structure ST. The plurality of conductive layers 110 are electrically insulated from configurations in another memory block BLK via the inter-block structure ST.

For example, as illustrated in FIG. 5, the inter-block structure ST includes a conductive layer 141 extending in the Z-direction and the X-direction and an insulating layer 142 of silicon oxide (SiO₂) or the like disposed on a side surface in the Y-direction of the conductive layer 141. The conductive layer 141 is connected to, for example, the semiconductor layer 112. The conductive layer 141 may include, for example, a stacked film of a barrier conductive film of titanium nitride (TiN) or the like and a metal film of tungsten (W) or the like. The conductive layer 141 functions as, for example, a part of the source line SL (FIG. 1).

The inter-block structure ST may be formed only of the insulating layer 142 without having the conductive layer 141 formed.

For example, as illustrated in FIG. 3 and FIG. 7, the hook-up region R_{HU} of the memory block BLK includes regions R_{HU_S} and a region R_{HU_W}.

### Region R_{HU_S}

For example, as illustrated in FIG. 3, FIG. 7, and FIG. 8, parts of the conductive layers 110 are disposed in the region R_{HU_S}. In addition, in the region R_{HU_S}, a contact electrode row CCSG (FIG. 8) is disposed for each string unit SU. Further, for example, as illustrated in FIG. 3, parts of the inter-string unit insulating layers SHE and an insulating layer SHE_V being in contact with end portions in the X-direction of the inter-string unit insulating layers SHE are disposed in the region R_{HU_S}. For example, as illustrated in FIG. 3, a plurality of supporting structures HR arranged in the X-direction and the Y-direction may be disposed in the region R_{HU_S}.

The conductive layers 110 (SGD) in the region R_{HU_S} are disposed continuously with the conductive layers 110 (SGD) in the memory hole region R_{MH} and electrically connected to them (FIG. 7, FIG. 8). In the region R_{HU_S}, two conductive layers 110 (SGD) mutually adjacent in the Y-direction are separated in the X-direction by the inter-string unit insulating layer SHE and not electrically connected to one another (FIG. 3).

Widths in the Y-direction of the conductive layers 110 (SGD) in the region R_{HU_S} may be different from widths in the Y-direction of the conductive layers 110 (SGD) in the memory hole region R_{MH}. For example, as illustrated in FIG. 3, the widths in the Y-direction of the conductive layers 110 (SGD) in the region R_{HU_S} may be provided such that the widths in the Y-direction of the conductive layers 110 (SGD) close to the inter-block structures ST are larger and the widths in the Y-direction of the conductive layers 110 (SGD) far from the inter-block structures ST are smaller.

The conductive layers 110 (WL) in the region R_{HU_S} are disposed continuously with the conductive layers 110 (WL) in the memory hole region R_{MH} and electrically connected to them (FIG. 7, FIG. 8). The conductive layers 110 (WL) in the region R_{HU_S} are not separated by the inter-string unit insulating layer SHE.

The inter-string unit insulating layers SHE in the region R_{HU_S} are basically disposed similarly to the inter-string unit insulating layers SHE in the memory hole region R_{MH}. The inter-string unit insulating layers SHE in the region R_{HU_S} are disposed continuously with the inter-string unit insulating layers SHE in the memory hole region R_{MH}. For example, as illustrated in FIG. 3, when the widths in the Y-direction of the conductive layers 110 (SGD) in the region R_{HU_S} are provided differently from the widths in the Y-direction of the conductive layers 110 (SGD) in the memory hole region R_{MH}, the inter-string unit insulating layers SHE may include parts extending in the X-direction and parts extending in a direction different from the X-direction, from the memory hole region R_{MH} to the region R_{HU_S}.

For example, as illustrated in FIG. 3 and FIG. 8, the insulating layer SHE_V is disposed between the conductive layers 110 (SGD) in the region R_{HU_S} and the conductive layers 110 (SGD) in the region R_{HU_W}. For example, the insulating layer SHE_V is disposed between contact electrodes CCS and contact electrodes CC. The insulating layer SHE_V extends, for example, in the Y-direction and the Z-direction. For example, as illustrated in FIG. 3, both end portions in the Y-direction of the insulating layer SHE_V are connected to the respective inter-block structures ST disposed at both end portions in the Y-direction of the memory block BLK.

For example, as illustrated in FIG. 8, a lower surface of the insulating layer SHE_V is disposed between the conductive layer 110 (SGD) positioned at the lowermost layer and the conductive layer 110 (WL) positioned at the uppermost layer. The insulating layer SHE_V separates the conductive layers 110 (SGD) in the region R_{HU_S} from the conductive layers 110 (SGD) in the region R_{HU_W} in the X-direction to electrically separate them. The insulating layer SHE_V does not separate the conductive layers 110 (WL). The insulating layer SHE_V contains, for example, silicon oxide (SiO₂) or the like.

For example, as illustrated in FIG. 8, the contact electrode row CCSG includes a plurality of contact electrodes CCS arranged in the X-direction.

The contact electrode CCS extends in the Z-direction and has a lower end connected to any one of the plurality of conductive layers 110 (SGD). The contact electrode CCS may include, for example, a stacked film of a barrier conductive film of titanium nitride (TiN) or the like and a metal film of tungsten (W) or the like. An insulating layer 170 of silicon oxide (SiO₂) or the like is disposed on an outer peripheral surface of the contact electrode CCS. The outer peripheral surface of the contact electrode CCS is surrounded by the conductive layers 110 (SGD) via the insulating layer 170.

In the following description, among the conductive layers 110 (SGD), an m-th (m is an integer of 1 or more) conductive layer 110 counting from above is referred to as a conductive layer 110(m−1) in some cases. In addition, among the plurality of contact electrodes CCS, the contact electrode CCS connected to a conductive layer 110(m) is referred to as a contact electrode CCS(m) in some cases.

FIG. 8 illustrates an example of contact electrodes CCS(0), CCS(1), CCS(4), CCS(5), which are disposed in the region R_{HU_S} in order from the one closest to the memory hole region R_{MH}.

Note that the respective contact electrodes CCS(m) disposed in the string units SUa, SUb, SUc, SUd, SUe arranged in the Y-direction may be disposed at different positions in the X-direction without all being arranged in the Y-direction (FIG. 3).

The supporting structures HR extend in the Z-direction and are disposed to penetrate the plurality of conductive layers 110 arranged in the Z-direction. The supporting structures HR contain, for example, silicon oxide (SiO₂).

### Region R_{HU_W}

For example, as illustrated in FIG. 3, FIG. 7, and FIG. 8, parts of the conductive layers 110 are disposed in the region R_{HU_W}. In addition, for example, two contact electrode rows CCG arranged in the Y-direction are disposed in the region R_{HU_W}. In FIG. 3, these two contact electrode rows CCG are denoted as contact electrode rows CCG(0), CCG(1). Further, similarly to the region R_{HU_S}, in the region R_{HU_W}, a plurality of supporting structures HR arranged in the X-direction and the Y-direction may be disposed.

The conductive layers 110 (SGD) in the region R_{HU_W} are separated in the X-direction from the conductive layers 110 (SGD) in the memory hole region R_{MH} and the region R_{HU_S} by the insulating layer SHE_V, are not disposed continuously with them, and are not electrically connected to them (FIG. 7, FIG. 8).

The conductive layers 110 (WL) in the region R_{HU_W} are disposed continuously with the conductive layers 110 (WL) in the memory hole region R_{MH} and the region R_{HU_S} and electrically connected to them (FIG. 7, FIG. 8).

For example, as illustrated in FIG. 8, the contact electrode row CCG includes a plurality of contact electrodes CC arranged in the X-direction.

The contact electrode CC extends in the Z-direction and has a lower end connected to any one of the conductive layers 110 (WL). The contact electrode CC may include, for example, a stacked film of a barrier conductive film of titanium nitride (TiN) or the like and a metal film of tungsten (W) or the like. An insulating layer 160 of silicon oxide (SiO₂) or the like is disposed on an outer peripheral surface of the contact electrode CC. The outer peripheral surface of the contact electrode CC is surrounded by the conductive layers 110 (SGD) and the conductive layers 110 (WL) via the insulating layer 160.

In the following description, among the conductive layers 110 (WL), an n-th (n is an integer of 1 or more) conductive layer 110 counting from above is referred to as a conductive layer 110(n−1) in some cases. In addition, among the plurality of contact electrodes CC, the contact electrode CC connected to a conductive layer 110(n) is referred to as a contact electrode CC(n) in some cases.

FIG. 8 illustrates an example of contact electrodes CC(0), CC(2), CC(4), CC(6) in the contact electrode row CCG(0), which are disposed in the region R_{HU_W} in order from the one closest to the memory hole region R_{MH}.

The contact electrodes CC(0), CC(2), CC(4), CC(6) in the contact electrode row CCG(0) may be arranged in the Y-direction with a plurality of contact electrodes CC(1), CC(3), CC(5), CC(7) in the contact electrode row CCG(1), respectively.

### Layer Structures of Conductive Layer 110 (SGD) and Conductive Layer 110 (WL)

For example, as illustrated in FIG. 7, the conductive layer 110 (SGD) includes a conductive layer 110I and a conductive layer 110II. The conductive layer 110I is opposed to the semiconductor layer 120 disposed in the memory hole region R_{MH} on one side and connected to the contact electrode CCS. The conductive layer 110II is opposed to the semiconductor layer 120 disposed in the memory hole region R_{MH} on the other side via the hook-up region R_{HU} and connected to the contact electrode CCS. In addition, for example, as illustrated in FIG. 7, an intermediate layer 110J is disposed at a layer including the conductive layer 110I and the conductive layer 110II. The intermediate layer 110J is a layer continuously formed in a region between the contact electrodes CC and the contact electrodes CC whose positions in the X-direction are different from one another and is not electrically connected to the conductive layer 110I or the conductive layer 110II.

The conductive layers 110I, 110II and the intermediate layer 110J contain the same material.

For example, as illustrated in FIG. 7, the conductive layer 110 (WL) includes a conductive layer 110III, which is a layer continuously formed in a region between the semiconductor layer 120 disposed in the memory hole region R_{MH} on one side and the semiconductor layer 120 disposed in the memory hole region R_{MH} on the other side via the hook-up region R_{HU}. The conductive layer 110III is opposed to these semiconductor layers 120.

The conductive layer 110III contains a same material as the conductive layers 110I, 110II and the intermediate layer 110J.

The insulating layer SHE_V is disposed between the conductive layer 110I and the intermediate layer 110J.

Next, a plurality of manufacturing methods for manufacturing the semiconductor memory device according to the first embodiment are described.

### Manufacturing Method 1

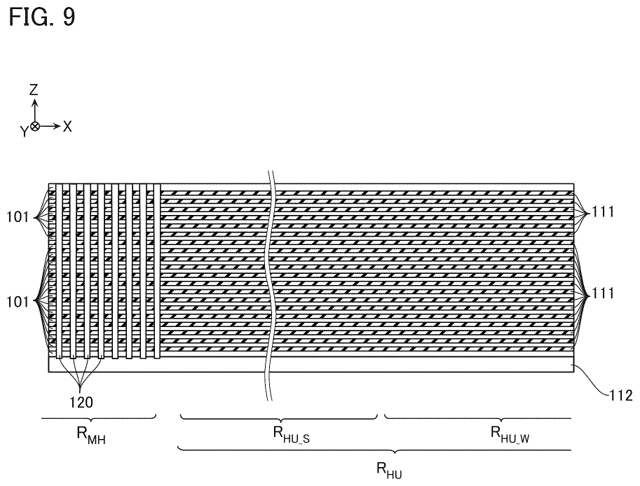

FIG. 9 to FIG. 13 are schematic cross-sectional views for describing a manufacturing method 1 of the semiconductor memory device according to the first embodiment. In the manufacturing method 1, the contact electrodes CC, CCS are simultaneously formed.

In the manufacturing method, for example, as illustrated in FIG. 9, the semiconductor layer 112 is formed on a (not illustrated in FIG. 9). In addition, the plurality of insulating layers 101 and a plurality of sacrifice layers 111 are alternately formed on or above the semiconductor layer 112. The sacrifice layers 111 contain, for example, silicon nitride (SiN) or the like. This process is performed by, for example, Chemical Vapor Deposition (CVD) or the like.

Next, for example, as illustrated in FIG. 9, the plurality of semiconductor layers 120 and the like are formed in the memory hole regions R_{MH}. In this process, openings that penetrate the plurality of insulating layers 101 and the plurality of sacrifice layers 111 are formed, and the gate insulating films 130 (FIG. 6), the semiconductor layers 120, and the like are formed on inner peripheral surfaces of these openings. This process is performed by, for example, Reactive Ion Etching (RIE), CVD, or the like.

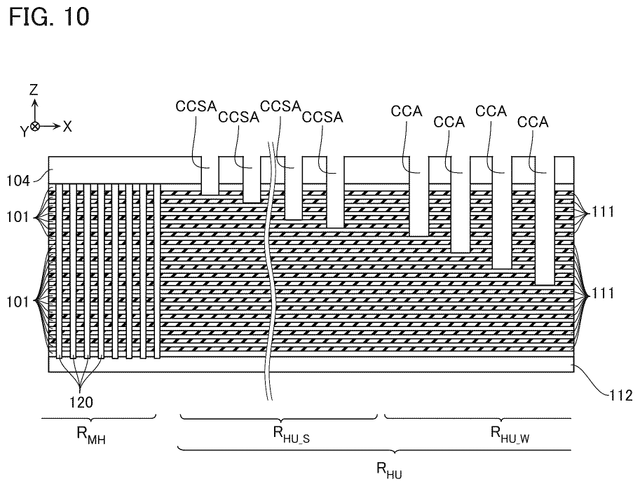

Next, for example, as illustrated in FIG. 10, after a hard mask 104 of amorphous silicon (α-Si) or the like is formed on an upper surface of the structure illustrated in FIG. 9, a plurality of openings CCA, CCSA are formed. The plurality of openings CCA, CCSA penetrate, for example, the hard mask 104, one or a plurality of insulating layers 101, and one or a plurality of sacrifice layers 111 to expose upper surfaces of any of the plurality of insulating layers 101. As the shallowest opening CCSA (not illustrated in FIG. 9), an opening that penetrates the hard mask 104 and has a lower end disposed in the uppermost insulating layer 101 may be formed. In this process, the formation and patterning of the hard mask 104 and removal of the insulating layers 101 and the sacrifice layers 111 by RIE or the like are repeated a plurality of times until each opening reaches a predetermined depth.

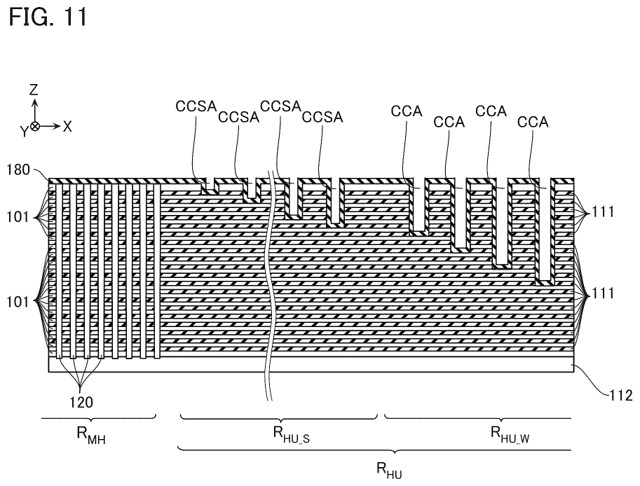

Next, for example, as illustrated in FIG. 11, the hard mask 104 is removed, and an insulating layer 180 containing a material similar to those of the insulating layers 160 and the insulating layers 170 is formed on an upper surface of the structure illustrated in FIG. 10 and inside the openings CCA, CCSA. This process is performed by, for example, CVD or the like.

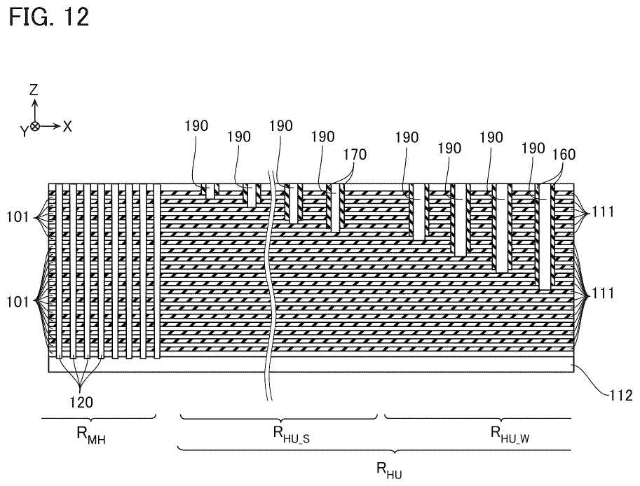

Next, for example, as illustrated in FIG. 12, parts of the insulating layer 180 on an upper surface of the structure illustrated in FIG. 11 and parts of the insulating layer 180 on bottom portions of the openings CCA, CCSA are removed, and a part of the insulating layer 101 closest to the bottom portion of each of the openings CCA, CCSA is removed for an amount of one layer, to form the insulating layers 160, 170. This process is performed by, for example, RIE or the like.

Next, for example, as illustrated in FIG. 12, sacrifice layers 190 of amorphous silicon (α-Si) or the like are formed inside the openings CCA, CCSA. This process is performed by, for example, CVD or the like.

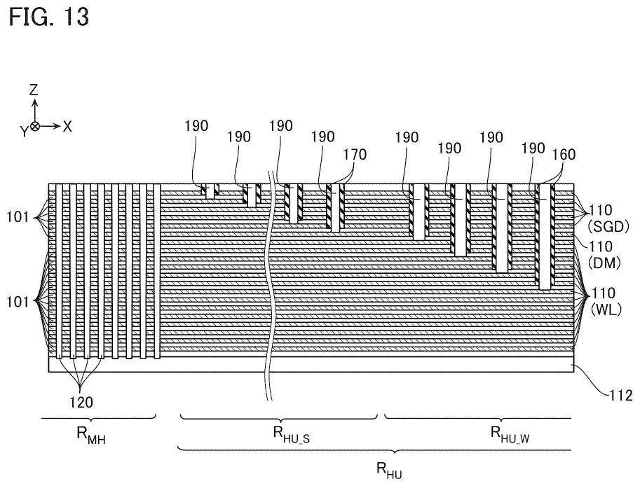

Next, for example, as illustrated in FIG. 13, the conductive layers 110 are formed. In this process, for example, by a method, such as RIE, openings that penetrate the plurality of insulating layers 101 and the plurality of sacrifice layers 111 are formed at positions corresponding to the inter-block structures ST (FIG. 3). Next, the plurality of sacrifice layers 111 are removed by wet etching or the like via these openings. Next, the plurality of conductive layers 110 are formed by a method, such as CVD.

Next, for example, as illustrated in FIG. 8, the sacrifice layers 190 are removed to form the contact electrodes CC, CCS. This process is performed by, for example, wet etching, CVD, or the like.

Next, for example, the inter-string unit insulating layers SHE and the insulating layers SHE_V as illustrated in FIG. 8 are formed. In this process, after openings that penetrate the plurality of insulating layers 101 and the plurality of conductive layers 110 are formed at positions corresponding to the inter-string unit insulating layers SHE and the insulating layers SHE_V, silicon oxide (SiO₂) and the like are formed in the openings. This process is performed by, for example, RIE, CVD, or the like.

Subsequently, by forming structures above the contact electrodes CC, CCS, such as the bit lines BL, the semiconductor memory device described with reference to FIG. 1 to FIG. 8 is formed.

### Manufacturing Method 2

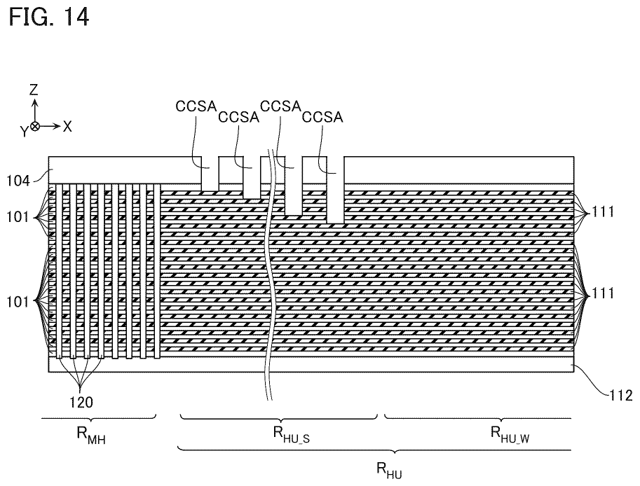

FIG. 14 to FIG. 16 are schematic cross-sectional views for describing a manufacturing method 2 of the semiconductor memory device according to the first embodiment. In the manufacturing method 2, the contact electrodes CCS are formed first, and the contact electrodes CC are then formed.

In the manufacturing method, processes similar to the processes described with reference to FIG. 9 are performed.

Next, for example, as illustrated in FIG. 14, a plurality of openings CCSA are formed at positions corresponding to the contact electrodes CCS. This process is performed similarly to the process described with reference to FIG. 10.

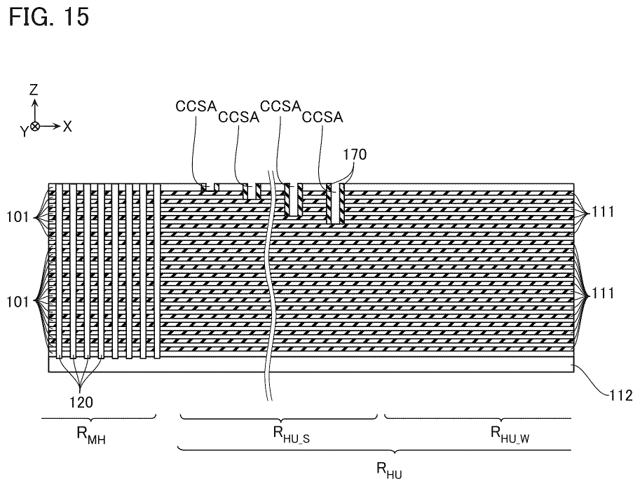

Next, for example, as illustrated in FIG. 15, the insulating layers 170 are formed. In this process, after insulating layers 180 are formed inside the openings CCSA similarly to the process illustrated in FIG. 11, parts of the insulating layers 180 at bottom portions of the openings CCSA are removed. This process is performed by, for example, CVD, RIE, or the like.

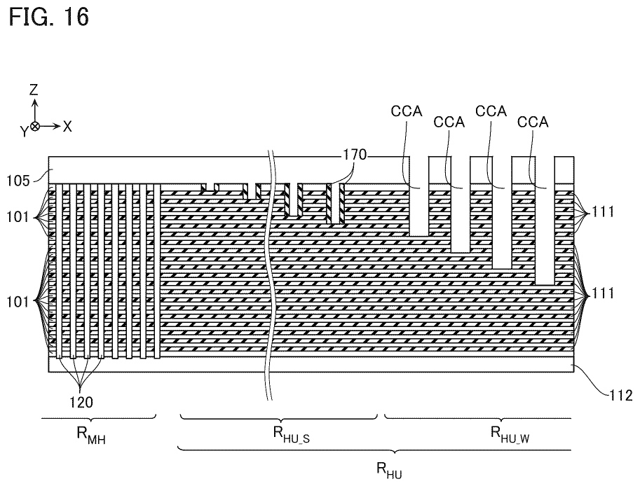

Next, for example, as illustrated in FIG. 16, a plurality of openings CCA are formed. In this process, a hard mask 105 of amorphous silicon (α-Si) or the like is formed on an upper surface of the structure illustrated in FIG. 15 and inside the openings CCSA, and the openings CCA are formed similarly to the process described with reference to FIG. 10.

Next, after processes similar to the processes described with reference to FIG. 11 to FIG. 13 are performed on the openings CCSA to form the insulating layers 160 and the conductive layers 110, the contact electrodes CC, CCS are formed.

Next, for example, similarly to the manufacturing method 1, the inter-string unit insulating layers SHE and the insulating layers SHE_V are formed.

Subsequently, by forming structures above the contact electrodes CC, CCS, such as the bit lines BL, the semiconductor memory device described with reference to FIG. 1 to FIG. 8 is formed.

### Manufacturing Method 3

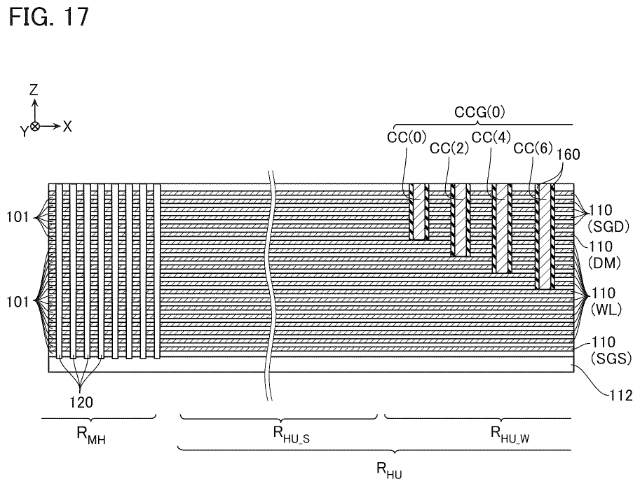

FIG. 17 to FIG. 19 are schematic cross-sectional views for describing a manufacturing method 3 of the semiconductor memory device according to the first embodiment. In the manufacturing method 3, the contact electrodes CC are formed first, and the contact electrodes CCS are then formed.

In the manufacturing method, the processes described with reference to FIG. 9 to FIG. 13 are performed only on the region R_{HU_W} to form the semiconductor layers 120, the plurality of conductive layers 110, the plurality of contact electrodes CC, and the like, as illustrated in FIG. 17.

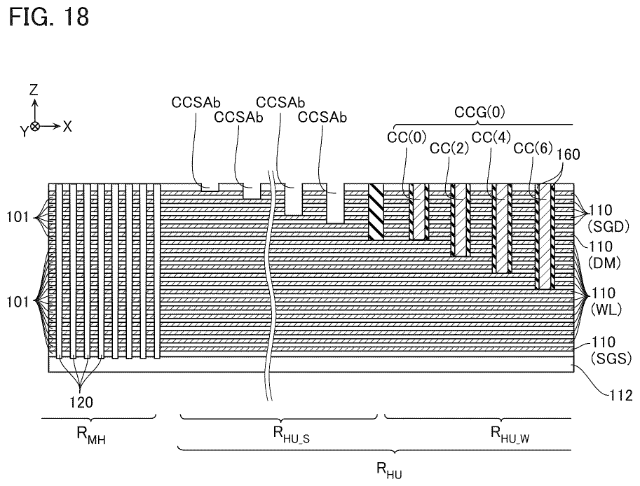

Next, for example, as illustrated in FIG. 18, a plurality of openings CCSAb are formed. The plurality of openings CCSAb penetrate one or a plurality of insulating layers 101 and zero or a plurality of conductive layers 110 to expose upper surfaces of any of the plurality of conductive layers 110 (SGD). This process is performed by, for example, RIE or the like.

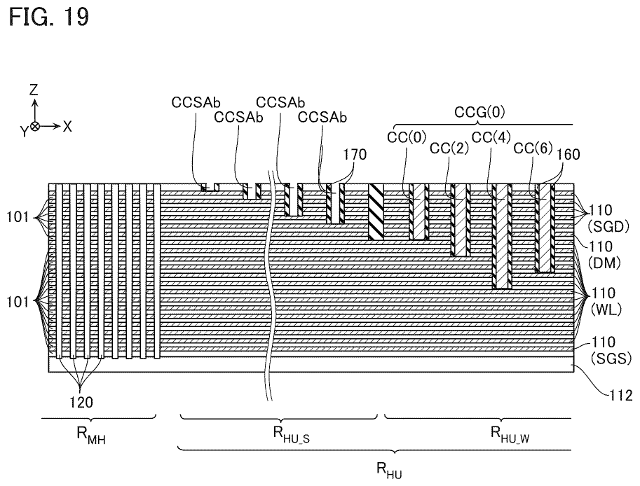

Next, for example, as illustrated in FIG. 19, insulating layers containing a material similar to that of the insulating layers 170 are formed inside the openings CCSAb, and parts of the insulating layers at bottom portions of the openings CCSAb are removed to form the insulating layers 170. This process is performed by, for example, CVD, RIE, or the like.

Next, the contact electrodes CCS are formed in the openings CCSAb. This process is performed by, for example, CVD or the like.

Next, for example, similarly to the manufacturing method 1, the inter-string unit insulating layers SHE and the insulating layers SHE_V are formed.

Subsequently, by forming structures above the contact electrodes CC, CCS, such as the bit lines BL, the semiconductor memory device described with reference to FIG. 1 to FIG. 8 is formed.

### Effects

In the semiconductor memory device according to the embodiment, as illustrated in FIG. 3, FIG. 7, and FIG. 8, the conductive layers 110 (SGD) contained in the respective string units SU in the regions R_{HU_S} are electrically separated from the conductive layers 110 (SGD) in the region R_{HU_W} by the insulating layers SHE_V. With such a configuration, the plurality of the conductive layers 110 (SGD) in the regions R_{HU_S} are not electrically conducted with one another via the conductive layers 110 (SGD) in the region R_{HU_W}. Accordingly, the conductive layers 110 (SGD) contained in the respective string units SU in the regions R_{HU_S} can be insulated from one another, and the string units SU can be electrically independent of one another, thus providing a semiconductor memory device that appropriately operates.

In addition, with the manufacturing method 1, the contact electrodes CC, CCS can be simultaneously formed, therefore reducing an increase in the number of manufacturing processes and providing a semiconductor memory device manufacturable at low cost.

### Modification 1 of First Embodiment

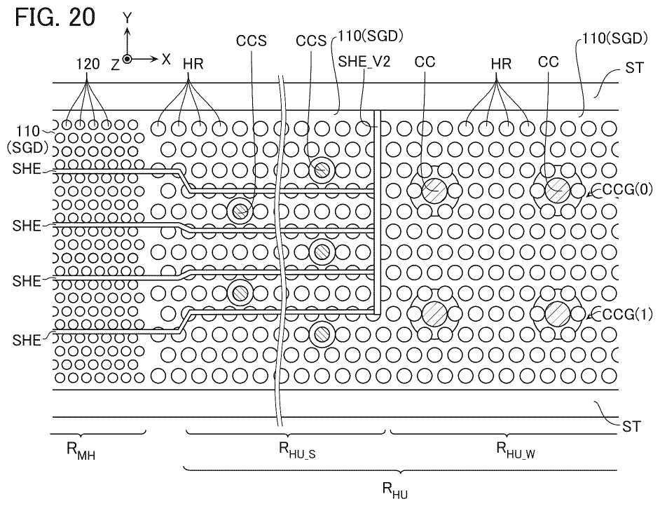

Next, with reference to FIG. 20, a modification 1 of the semiconductor memory device according to the first embodiment is described. FIG. 20 is a schematic plan view illustrating a part of a configuration of the semiconductor memory device according to the modification.

In the semiconductor memory device according to the modification, the insulating layers SHE_V (FIG. 3) are not disposed, but insulating layers SHE_V2 (FIG. 20) are disposed instead.

The insulating layer SHE_V2 is basically configured similarly to the insulating layer SHE_V (FIG. 3). However, an end portion on one side in the Y-direction of the insulating layer SHE_V2 is not in contact with the inter-block structure ST disposed on one side in the Y-direction of the memory block BLK. An end portion on the other side in the Y-direction of the insulating layer SHE_V2 is in contact with the inter-block structure ST disposed on the other side in the Y-direction of the memory block BLK.

In the modification, among the five conductive layers 110 (SGD) in the region R_{HU_S}, the first conductive layer 110 (SGD) counting from the negative side in the Y-direction in FIG. 20 is electrically connected to the conductive layer 110 (SGD) in the region R_{HU_W}. On the other hand, the second to fifth conductive layers 110 (SGD) counting from the negative side in the Y-direction in FIG. 20 are electrically separated from the conductive layer 110 (SGD) in the region R_{HU_W} by the insulating layer SHE_V2. Even with such a configuration, the five conductive layers 110 (SGD) in the region R_{HU_S} are not electrically conducted with one another via the conductive layer 110 (SGD) in the region R_{HU_W}. Accordingly, even with such a structure as the modification, the five conductive layers 110 (SGD) in the region R_{HU_S} can be insulated from one another, and the string units SU can be electrically independent of one another.

### Modification 2 of First Embodiment

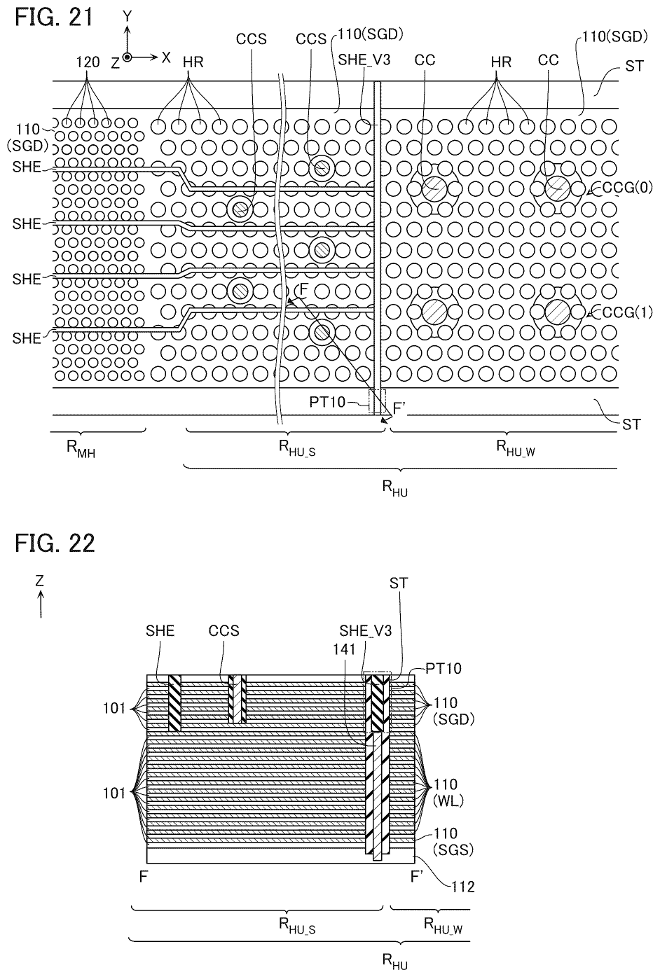

Next, with reference to FIG. 21 and FIG. 22, a modification 2 of the semiconductor memory device according to the first embodiment is described. FIG. 21 is a schematic plan view illustrating a part of a configuration of the semiconductor memory device according to the modification. FIG. 22 illustrates a cross-sectional surface of the structure illustrated in FIG. 21 taken along the line F-F′ and viewed along a direction of arrows.

In the semiconductor memory device according to the modification, the insulating layers SHE_V (FIG. 3) are not disposed, but insulating layers SHE_V3 (FIG. 21) are disposed instead.

The insulating layer SHE_V3 is basically configured similarly to the insulating layer SHE_V (FIG. 3). However, the insulating layer SHE_V3 extends in the Y-direction across the memory block BLK and the inter-block structures ST disposed on both sides in the Y-direction of the memory blocks BLK. For example, as illustrated in FIG. 22, at an intersection portion PT10 (FIG. 22) between the inter-block structure ST and the insulating layer SHE_V3, an upper surface of the conductive layer 141 contained in the inter-block structure ST is in contact with a lower surface of the insulating layer SHE_V3.

For example, as illustrated in FIG. 22, a position of the upper surface of the conductive layer 141 at the intersection portion PT10 may be disposed between the conductive layer 110 (SGD) positioned at the lowermost layer and the conductive layer 110 (WL) positioned at the uppermost layer.

### Second Embodiment

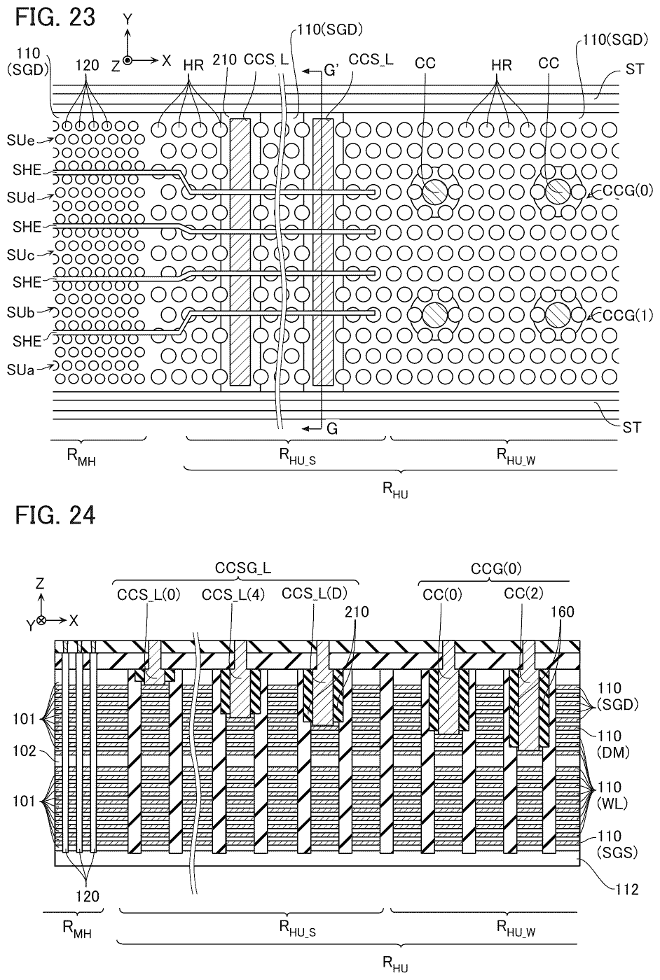

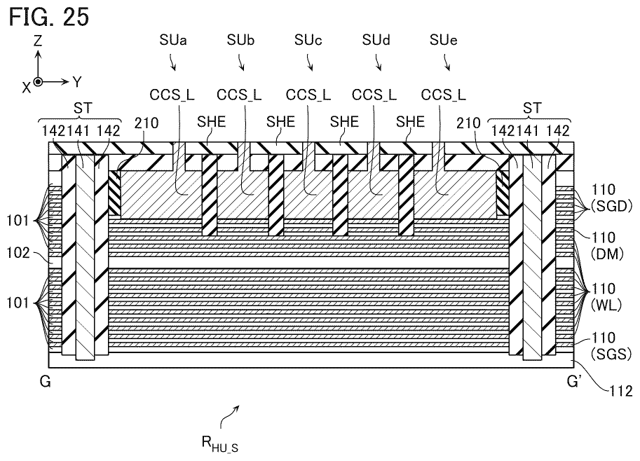

FIG. 23 is a schematic plan view illustrating a part of a configuration of a semiconductor memory device according to the embodiment. FIG. 23 is a schematic enlarged view of a part indicated by A in FIG. 2. FIG. 24 and FIG. 25 are schematic cross-sectional views illustrating a part of the configuration of the semiconductor memory device according to the embodiment. FIG. 25 is a schematic cross-sectional view of the structure illustrated in FIG. 23 taken along the line G-G′ and viewed along a direction of arrows. In the following description, parts similar to those of the first embodiment are attached by similar reference numerals, and their descriptions are omitted.

The semiconductor memory device according to the embodiment is basically configured similarly to the semiconductor memory device according to the first embodiment. However, in the semiconductor memory device (FIG. 23) according to the embodiment, the insulating layers SHE_V (FIG. 3) are not disposed.

In the semiconductor memory device according to the embodiment, instead of the contact electrode row CCSG (FIG. 8), contact electrode rows CCSG_L (FIG. 24) are disposed in the regions R_{HU_S}. In addition, in the semiconductor memory device according to the embodiment, insulating layers 210 are disposed.

The contact electrode rows CCSG_L are each disposed in each string unit SU. For example, as illustrated in FIG. 24, the contact electrode row CCSG_L includes a plurality of contact electrodes CCS_L arranged in the X-direction.

The contact electrode CCS_L extends in the Z-direction and has a lower end connected to any one of the plurality of conductive layers 110 (SGD). The contact electrode CCS_L may include, for example, a stacked film of a barrier conductive film of titanium nitride (TiN) or the like and a metal film of tungsten (W) or the like.

In the following description, among the plurality of contact electrodes CCS_L, the contact electrode CCS_L connected to the conductive layer 110(m) is referred to as a contact electrode CCS_L(m) in some cases.

FIG. 24 illustrates an example of contact electrodes CCS_L(0), CCS_L(4), which are disposed in the region R_{HU_S} in order from the one closest to the memory hole region R_{MH}. In addition, among the plurality of contact electrodes CCS_L, the contact electrode CCS_L connected to the conductive layer 110 (DM) is denoted as a contact electrode CCS_L(D).

For example, in the example illustrated in FIG. 25, the respective contact electrodes CCS_L(m) disposed in the string units SUa, SUb, SUc, SUd, SUe arranged in the Y-direction are all arranged in the Y-direction. An inter-string unit insulating layer SHE is disposed between the respective contact electrodes CCS_L(m) disposed in two adjacent string units SU. The respective contact electrodes CCS_L(m) disposed in two adjacent string units SU are insulated by the inter-string unit insulating layer SHE. For example, as illustrated in FIG. 25, at least one of both side surfaces in the Y-direction of the contact electrode CCS_L is in contact with the inter-string unit insulating layer SHE.

For example, as illustrated in FIG. 23, the insulating layer 210 is disposed so as to surround outer peripheral surfaces of the contact electrodes CCS_L(m) arranged in the Y-direction. The insulating layer 210 separates the conductive layers 110 (SGD) in the region R_{HU_S} from the conductive layers 110 (SGD) in the region R_{HU_W} in the X-direction to electrically separate them. The insulating layer 210 does not separate the conductive layers 110 (WL). The insulating layer 210 contains, for example, silicon oxide (SiO₂) or the like.

For example, as illustrated in FIG. 23 and FIG. 24, parts of the insulating layer 210 are disposed on both side surfaces in the X-direction of the contact electrode CCS_L. Both side surfaces in the X-direction of the contact electrode CCS_L are surrounded by the conductive layers 110 (SGD) via the insulating layer 210.

In addition, parts of the insulating layer 210 are also disposed on side surfaces (FIG. 23, FIG. 25) on the inter-block structure ST sides in the Y-direction of the contact electrodes CCS_L disposed in the string units SUa, SUe, which are closest to the inter-block structures ST.

### Manufacturing Method

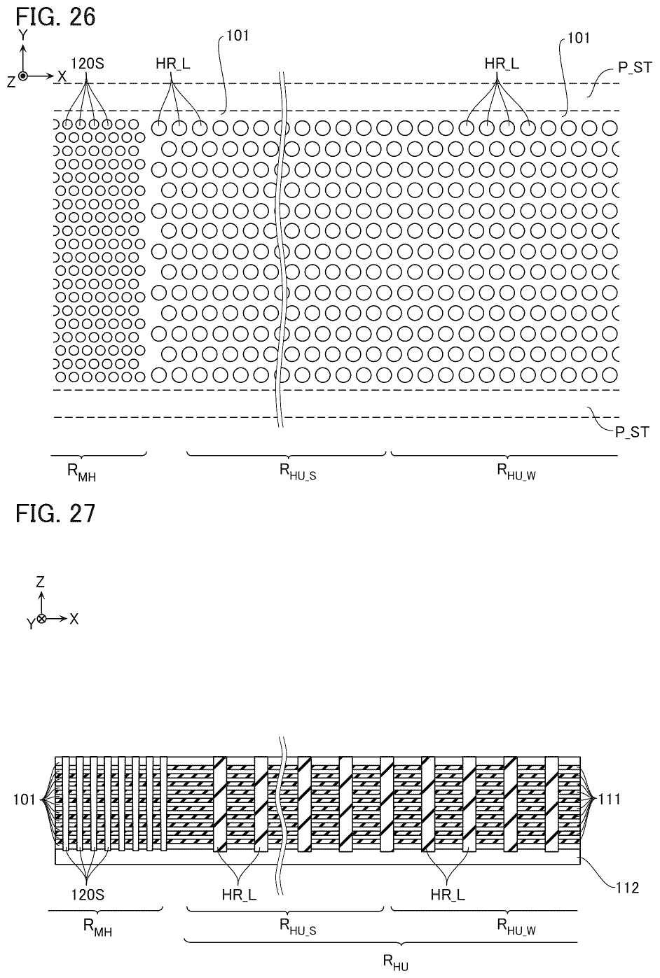

FIG. 26 to FIG. 46 are schematic cross-sectional views for describing a method for manufacturing the semiconductor memory device according to the second embodiment.

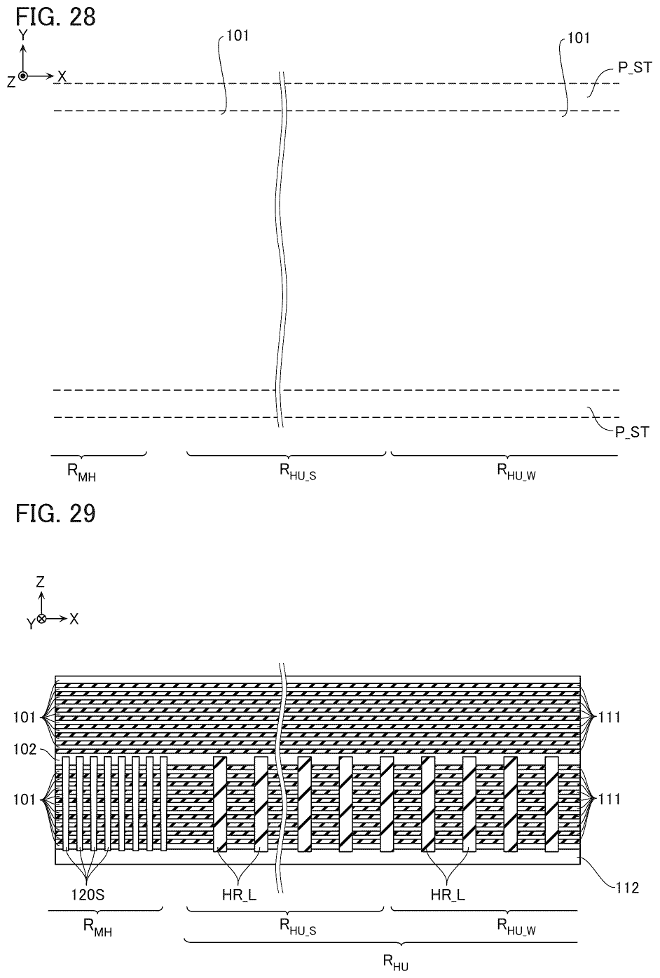

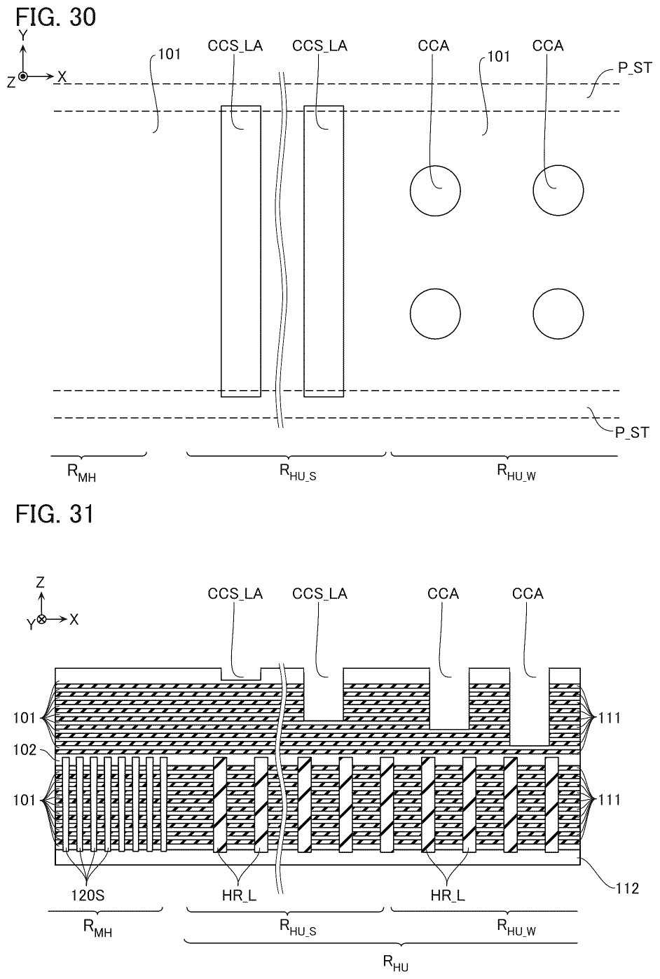

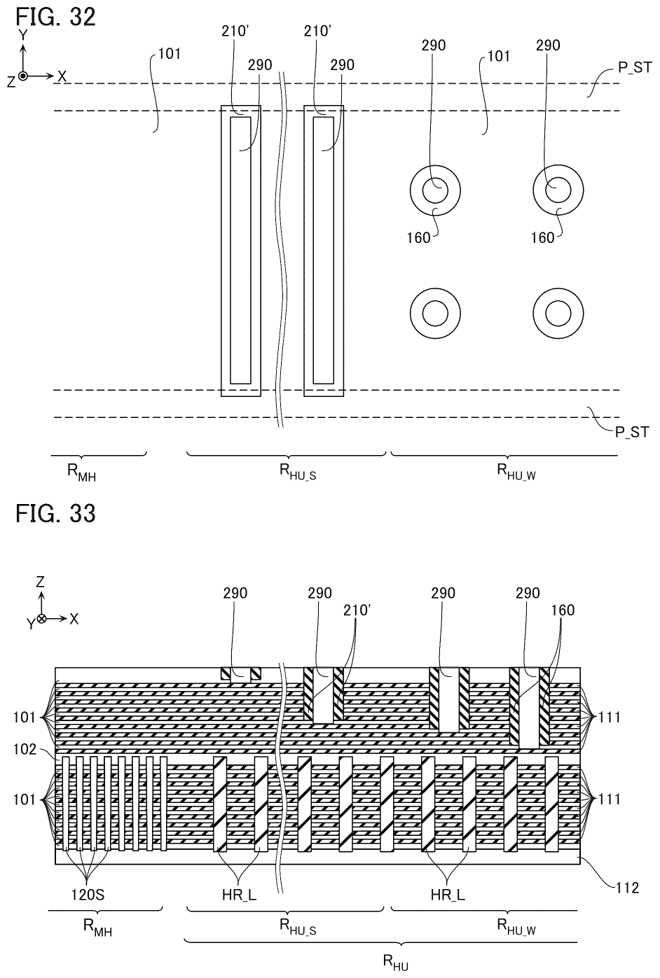

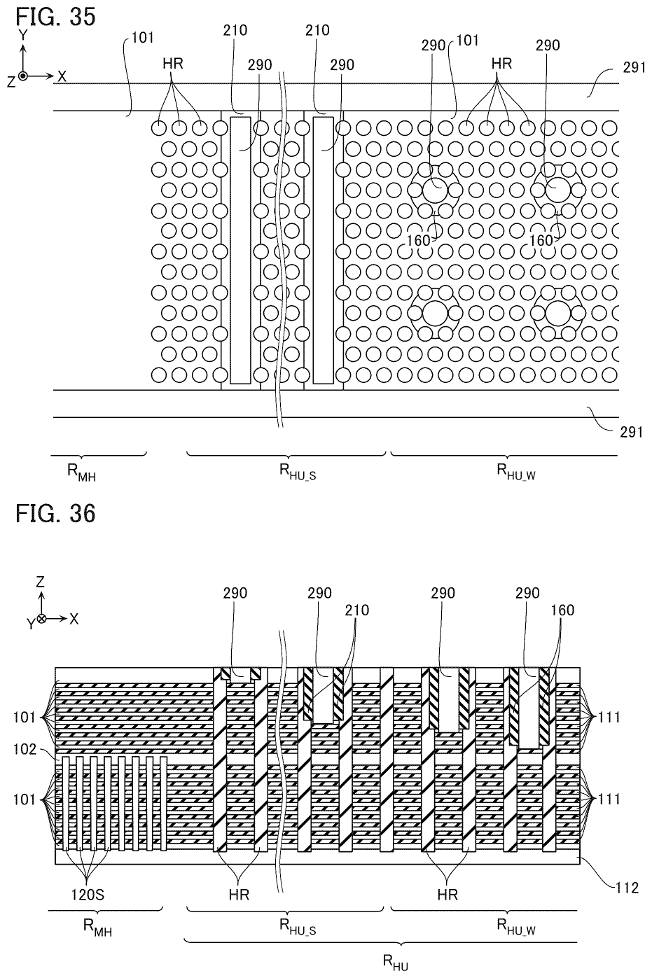

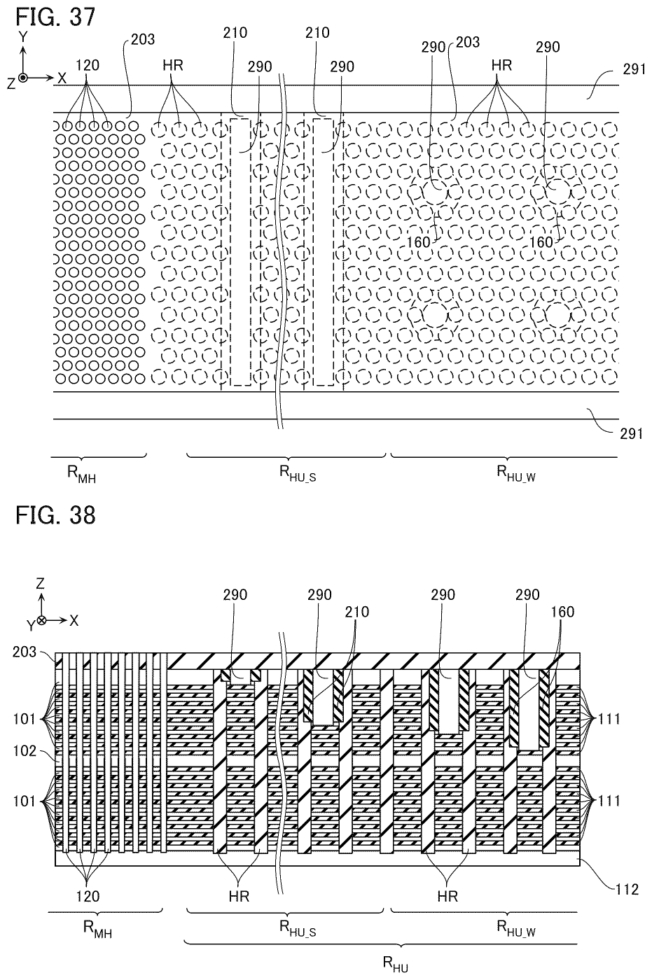

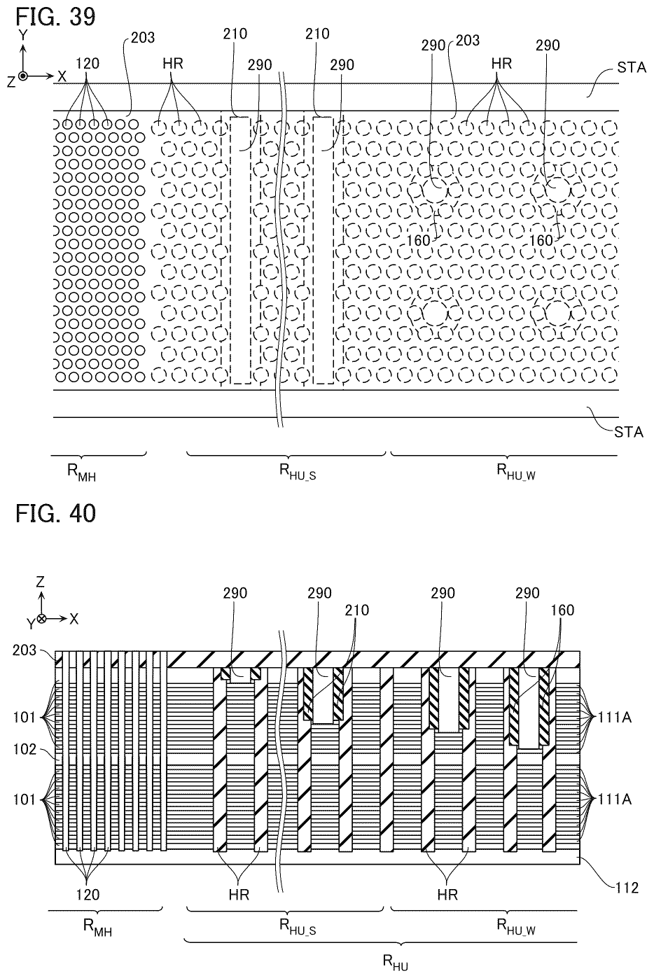

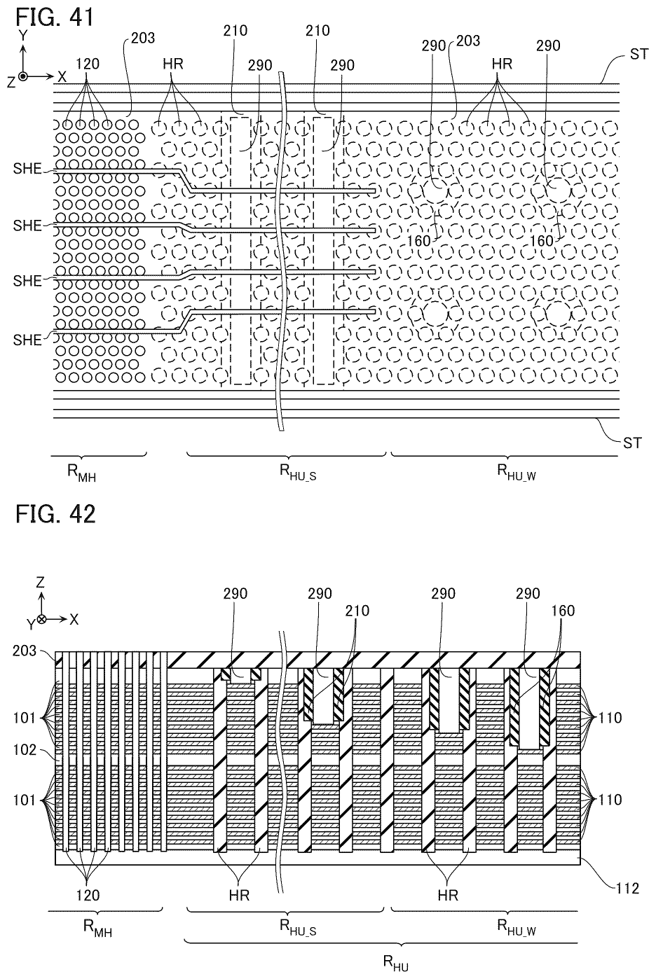

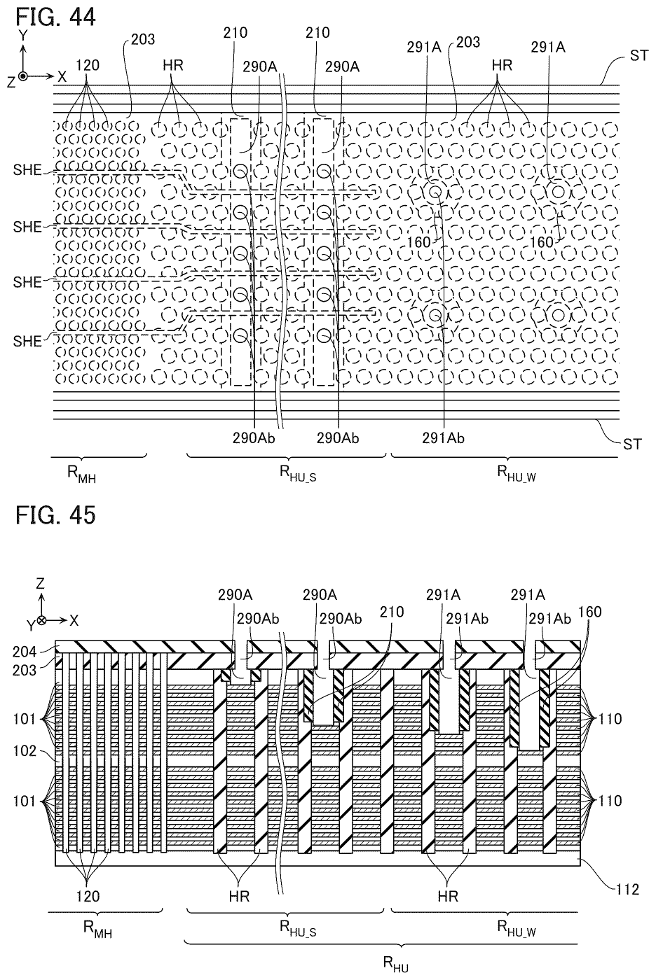

FIG. 26, FIG. 28, FIG. 30, FIG. 32, FIG. 35, FIG. 37, FIG. 39, FIG. 41, and FIG. 44 illustrate plan views corresponding to FIG. 23. In FIG. 26, FIG. 28, FIG. 30, and FIG. 32, regions P_ST corresponding to the inter-block structures ST are indicated by dotted lines.

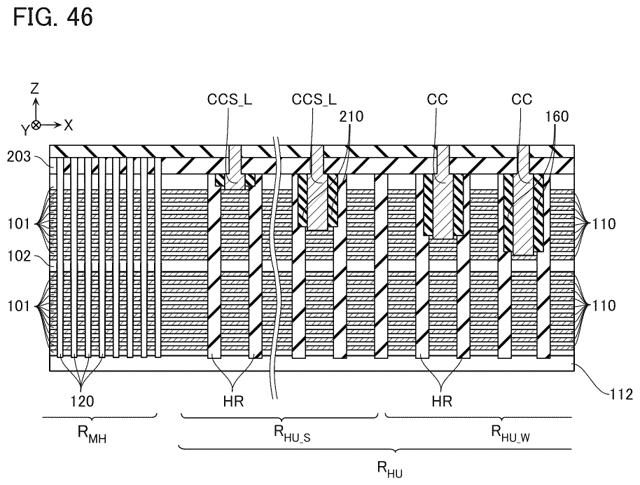

FIG. 27, FIG. 29, FIG. 31, FIG. 33, FIG. 36, FIG. 38, FIG. 40, FIG. 42, FIG. 45, and FIG. 46 illustrate cross-sectional surfaces corresponding to FIG. 24.

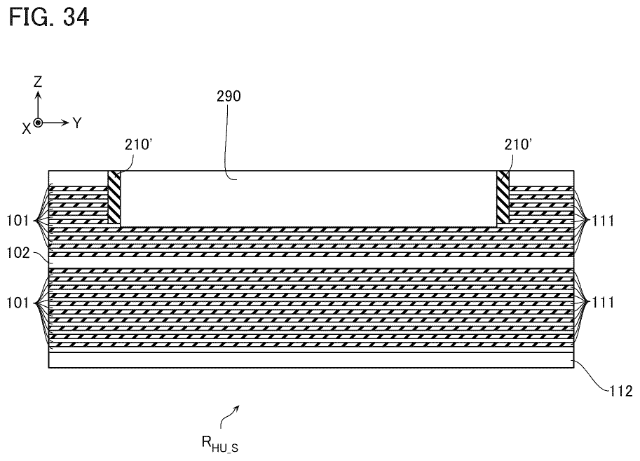

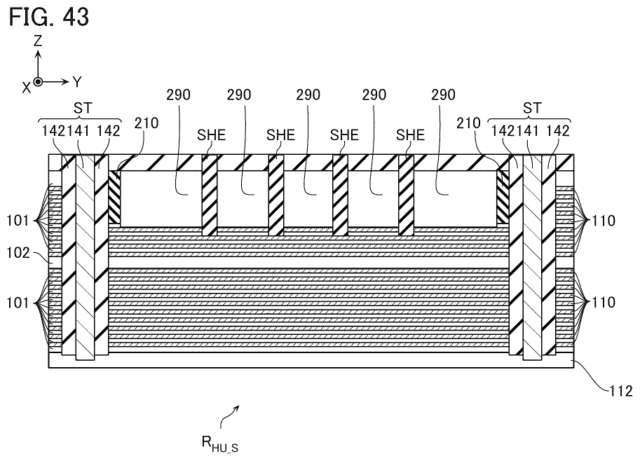

FIG. 34 and FIG. 43 illustrate cross-sectional surfaces corresponding to FIG. 25.

In the manufacturing method, for example, as illustrated in FIG. 26 and FIG. 27, the semiconductor layer 112 is formed on a substrate (not illustrated in FIG. 26 and FIG. 27). In addition, the plurality of insulating layers 101 and the plurality of sacrifice layers 111 are alternately formed on and above the semiconductor layer 112. This process is performed by, for example, CVD or the like.

Next, for example, as illustrated in FIG. 26 and FIG. 27, a plurality of sacrifice layers 120S are formed in the memory hole region R_{MH}. In this process, openings that penetrate the plurality of insulating layers 101 and the plurality of sacrifice layers 111 are formed, and the sacrifice layers 120S of amorphous silicon (α-Si) or the like are formed inside these openings. This process is performed by, for example, RIE, CVD, or the like.

Next, for example, as illustrated in FIG. 26 and FIG. 27, supporting structures HR_L are formed in the hook-up region R_{HU}. In this process, openings that penetrate the plurality of insulating layers 101 and the plurality of sacrifice layers 111 are formed, and insulating layers containing silicon oxide (SiO₂) or the like are formed inside these openings. This process is performed by, for example, RIE, CVD, or the like. The process of forming the openings for the supporting structures HR_L may be performed simultaneously with the process of forming the openings for the sacrifice layers 120S.

Next, for example, as illustrated in FIG. 28 and FIG. 29, on an upper surface of the structure illustrated in FIG. 27, an insulating layer 102 of silicon oxide (SiO₂) or the like is formed, and the plurality of insulating layers 101 and the plurality of sacrifice layers 111 are alternately formed. This process is performed by, for example, CVD or the like.

Next, for example, as illustrated in FIG. 30 and FIG. 31, a plurality of openings CCA, CCS_LA are formed. For example, as illustrated in FIG. 31, the openings CCS_LA extend in the Z-direction and penetrate one or a plurality of insulating layers 101 and one or a plurality of sacrifice layers 111 to expose upper surfaces of any of the plurality of insulating layers 101. Note that a bottom surface of the shallowest opening CCS_LA may be disposed above an upper surface of the uppermost sacrifice layer 111. In addition, for example, as illustrated in FIG. 30, the openings CCS_LA are disposed as line shapes extending in the Y-direction across the memory block BLK and parts of the regions P_ST where the inter-block structures ST are formed. The plurality of openings CCA, CCS_LA are formed, for example, similarly to the process described with reference to FIG. 10.

Next, for example, as illustrated in FIG. 32 to FIG. 34, inside the plurality of openings CCA, CCS_LA, insulating layers 210′and the insulating layers 160 containing a material similar to that of the insulating layers 210 are formed respectively, and sacrifice layers 290 of amorphous silicon (α-Si) or the like are formed. In this process, insulating layers containing materials similar to those of the insulating layers 210, 160 are formed inside the plurality of openings CCA, CCS_LA, respectively, and parts of the insulating layers at bottom portions of the plurality of openings CCA, CCS_LA are removed to form the insulating layers 210′, 160. Next, the sacrifice layers 290 are formed inside the plurality of openings CCA, CCS_LA. This process is performed by, for example, CVD, RIE, or the like.

Next, for example, as illustrated in FIGS. 35 and 36, the supporting structures HR, the insulating layers 210, and sacrifice layers 291 are formed. In this process, openings that penetrate the plurality of insulating layers 101 and the plurality of sacrifice layers 111 are formed above the supporting structures HR_L, and openings that penetrate the plurality of insulating layers 101 and the plurality of sacrifice layers 111 to expose the semiconductor layer 112 are formed in the regions P_ST. When the openings are formed in the regions P_ST, both side surfaces in the Y-direction of the insulating layers 210′ are simultaneously removed to form the insulating layers 210. Next, insulating layers containing silicon oxide (SiO₂) or the like are formed inside the openings above the supporting structures HR_L to form the supporting structures HR, and the sacrifice layers 291 of amorphous silicon (α-Si) or the like are formed in the openings formed in the regions P_ST. This process is performed by, for example, RIE, CVD, or the like.

Next, for example, as illustrated in FIG. 37 and FIG. 38, an insulating layer 203 of silicon oxide (SiO₂) or the like is formed on an upper surface of the structure illustrated in FIG. 36. This process is performed by, for example, CVD or the like.

Next, for example, as illustrated in FIG. 37 and FIG. 38, openings that penetrate the insulating layer 203 above the sacrifice layers 120S, the plurality of insulating layers 101, and the plurality of sacrifice layers 111 to expose upper surfaces of the sacrifice layers 120S are formed. After the sacrifice layers 120S are removed via the openings, the gate insulating films 130, the semiconductor layers 120, and the like are formed inside the openings. This process is performed by, for example, CVD, RIE, or the like.

Next, for example, as illustrated in FIG. 39, the sacrifice layers 291 are removed to form openings STA. The openings STA extend in the Z-direction and penetrate the plurality of insulating layers 101 and the plurality of sacrifice layers 111 to expose the semiconductor layer 112. This process is performed by, for example, wet etching or the like.

Next, for example, as illustrated in FIG. 40, the sacrifice layers 111 are removed via the openings STA to form openings 111A. This process is performed by, for example, wet etching or the like.

Next, for example, as illustrated in FIG. 41 and FIG. 42, the conductive layers 110 are formed via the openings STA. In addition, the inter-block structures ST are formed in the openings STA. This process is performed by, for example, CVD, RIE, or the like.

Next, for example, as illustrated in FIG. 41 to FIG. 43, the inter-string unit insulating layers SHE are formed. In this process, after openings that penetrate the insulating layer 203, the plurality of insulating layers 101, the plurality of conductive layers 110, and the plurality of sacrifice layers 290 are formed at positions corresponding to the inter-string unit insulating layers SHE, silicon oxide (SiO₂) or the like is formed in the openings. This process is performed by, for example, RIE, CVD, or the like.

Next, for example, as illustrated in FIG. 44 and FIG. 45, an insulating layer 204 of silicon oxide (SiO₂) or the like is formed on an upper surface of the structure illustrated in FIG. 42, and parts of the insulating layers 203, 204 above the sacrifice layers 290 are removed to form openings 290Ab, 291Ab. The openings 290Ab, 291Ab penetrate the insulating layers 203, 204 to expose upper surfaces of the sacrifice layers 290. This process is performed by, for example, RIE or the like.

Next, for example, as illustrated in FIG. 44 and FIG. 45, the sacrifice layers 290 are removed via the openings 290Ab, 291Ab to form openings 290A, 291A. This process is performed by, for example, wet etching or the like.

Next, for example, as illustrated in FIG. 46, the contact electrodes CCS_L, CC are formed in the openings 290A, 290Ab, 291A, 291Ab. This process is performed by, for example, CVD or the like.

Subsequently, by forming structures above the contact electrodes CC, CCS_L, such as the bit lines BL, the semiconductor memory device described with reference to FIG. 23 to FIG. 25 is formed.

### Effects

In the semiconductor memory device according to the embodiment, as illustrated in FIG. 23 and FIG. 24, the conductive layers 110 (SGD) contained in the respective string units SU in the regions R_{HU_S} are electrically separated from the conductive layers 110 (SGD) in the region R_{HU_W} by the insulating layers 210. With such a configuration, the plurality of the conductive layers 110 (SGD) in the regions R_{HU_S} are not electrically conducted with one another via the conductive layers 110 (SGD) in the region R_{HU_W}. Accordingly, the conductive layers 110 (SGD) contained in the respective string units SU in the regions R_{HU_S} can be insulated from one another, and the string units SU can be electrically independent of one another, thus providing a semiconductor memory device that appropriately operates.

In addition, with the manufacturing method according to the embodiment, the plurality of openings CCA, CCS_LA (FIG. 31) to form the contact electrodes CC, CCS_L can be collectively formed, therefore reducing an increase in the number of manufacturing processes and providing a semiconductor memory device manufacturable at low cost.

### Third Embodiment

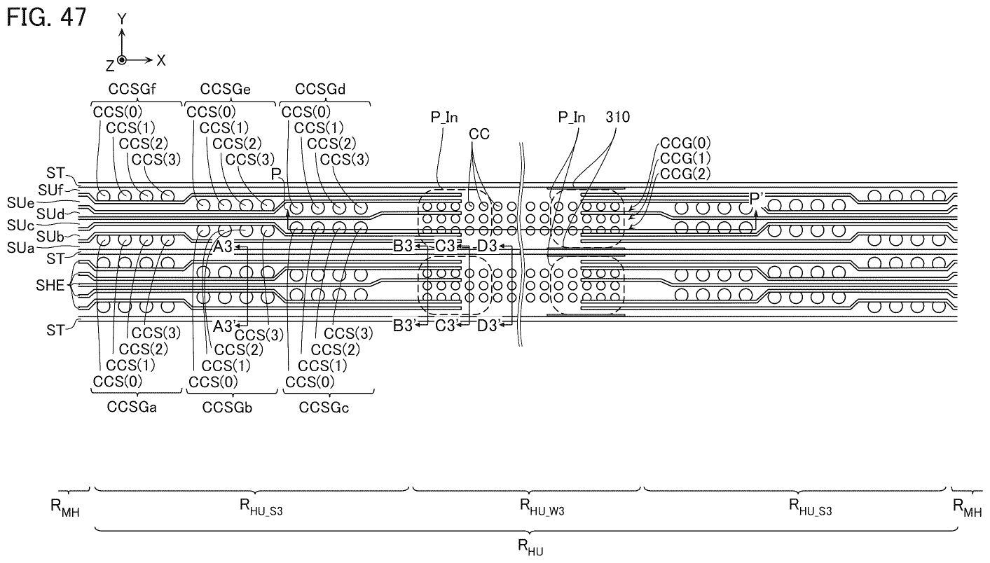

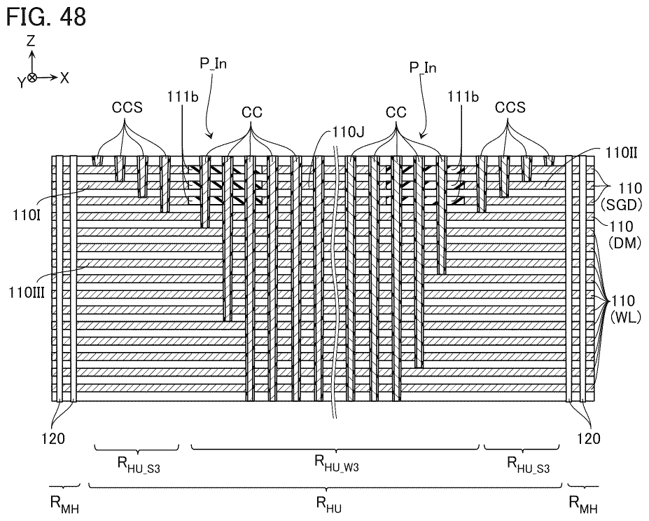

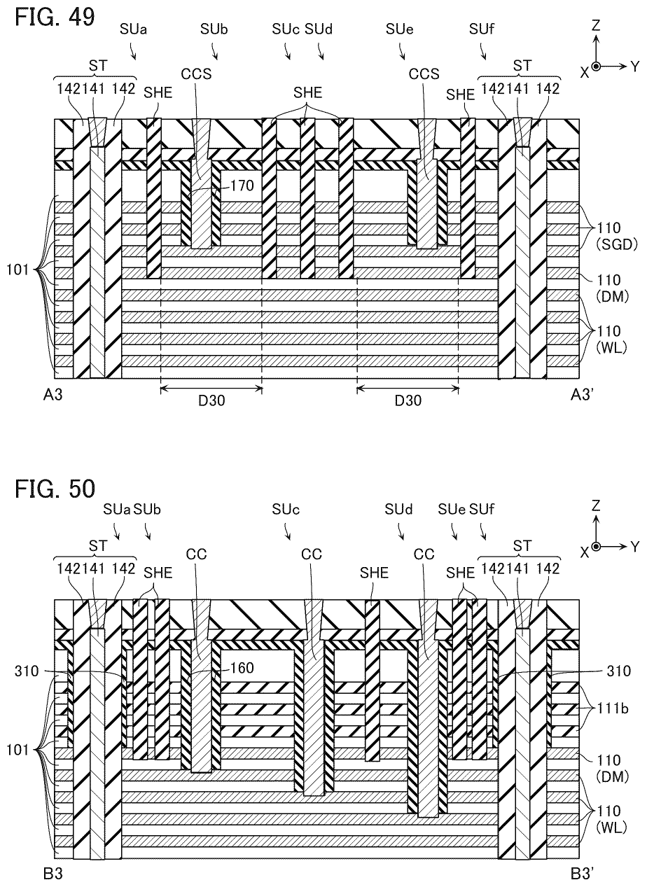

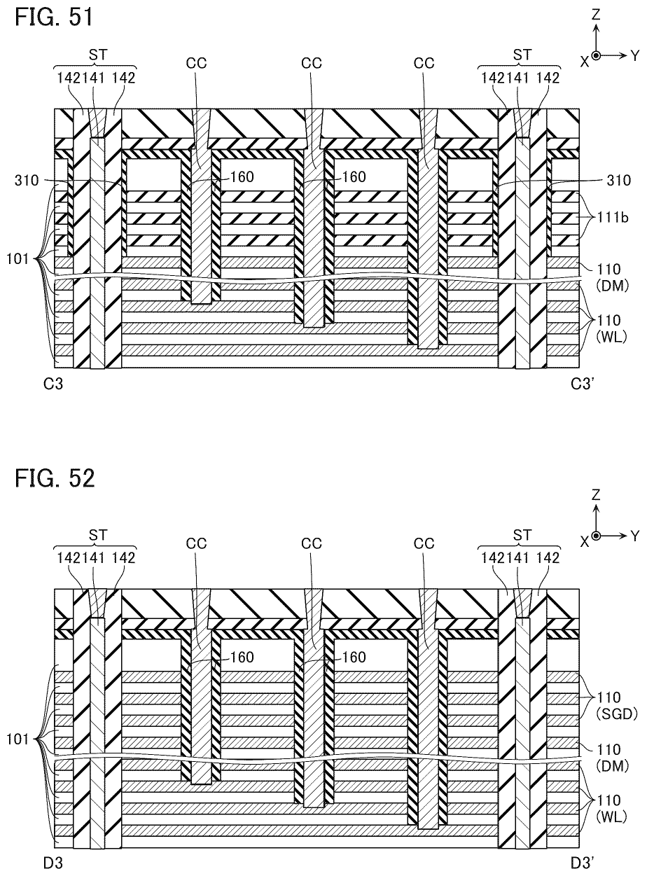

FIG. 47 is a schematic plan view illustrating a part of a configuration of a semiconductor memory device according to a third embodiment. FIG. 48 to FIG. 52 are schematic cross-sectional views illustrating parts of the configuration of the semiconductor memory device according to the embodiment. FIG. 48 is a schematic cross-sectional view of the structure illustrated in FIG. 47 taken along the line P-P′ and viewed along a direction of arrows. FIG. 49 is a schematic cross-sectional view of the structure illustrated in FIG. 47 taken along the line A3-A3′ and viewed along a direction of arrows. FIG. 50 is a schematic cross-sectional view of the structure illustrated in FIG. 47 taken along the line B3-B3′ and viewed along a direction of arrows. FIG. 51 is a schematic cross-sectional view of the structure illustrated in FIG. 47 taken along the line C3-C3′ and viewed along a direction of arrows. FIG. 52 is a schematic cross-sectional view of the structure illustrated in FIG. 47 taken along the line D3-D3′ and viewed along a direction of arrows. In the following description, parts similar to those of the first embodiment are attached by similar reference numerals, and their descriptions are omitted.

The semiconductor memory device according to the embodiment is basically configured similarly to the semiconductor memory device according to the first embodiment. However, the semiconductor memory device (FIG. 47) according to the embodiment includes regions R_{HU_S3}, R_{HU_W3} instead of the regions R_{HU_S}, R_{HU_W}. In addition, in the semiconductor memory device according to the embodiment, for example, six string units SU arranged in the Y-direction are disposed. In the example illustrated in FIG. 47, the six string units SU are denoted as string units SUa, SUb, SUc, SUd, SUe, SUf from the negative side in the Y-direction. Further, in the semiconductor memory device according to the embodiment, for example, three contact electrode rows CCG arranged in the Y-direction are disposed in the region R_{HU_W3}. In the example illustrated in FIG. 47, these three contact electrode rows CCG are denoted as contact electrode rows CCG(0), CCG(1), CCG(2).

The regions R_{HU_S3}, R_{HU_W3} (FIG. 47) are basically configured similarly to the regions R_{HU_S}, R_{HU_W} (FIG. 3). However, in the semiconductor memory device according to the embodiment, the insulating layers SHE_V (FIG. 7) are not disposed in the regions R_{HU_S3} (FIG. 48), but regions P_In (FIG. 47, FIG. 48) are disposed instead.

For example, as illustrated in FIG. 47 and FIG. 48, the regions P_In are disposed at both end portions in the X-direction of the region R_{HU_W3}. For example, as illustrated in FIG. 48, in the regions P_In, insulating layers 111b are disposed at layers disposed at the same height positions as the conductive layers 110 (SGD).

For example, as illustrated in FIG. 48, the insulating layers 111b are disposed between the conductive layers 110 (SGD) disposed in the regions R_{HU_S3} and the conductive layers 110 (SGD) disposed in the region R_{HU_W3}. The insulating layers 111b extend, for example, in the X-direction and the Y-direction. For example, as illustrated in FIG. 50 and FIG. 51, both end portions in the Y-direction of the insulating layers 111b are in contact with the respective inter-block structures ST. The insulating layers 111b separate the conductive layers 110 (SGD) in the regions R_{HU_S3} from the conductive layers 110 (SGD) in the region R_{HU_W3} in the X-direction to electrically separate them. The insulating layers 111b contain a material similar to that of the sacrifice layers 111, such as silicon nitride (SiN).

For example, as illustrated in FIG. 47, end portions on the region R_{HU_W3} side in the X-direction of the inter-string unit insulating layers SHE are disposed inside the regions P_In.

In the regions R_{HU_S3} (FIG. 47), contact electrode rows CCSGa, CCSGb, CCSGc, CCSGd, CCSGe, CCSGf are disposed in the string units SUa, SUb, SUc, SUd, SUe, SUf, respectively.

The contact electrode rows CCSGa to CCSGf are basically disposed similarly to the contact electrode row CCSG (FIG. 8) and include, for example, a plurality of contact electrodes CCS arranged in the X-direction. However, as illustrated in FIG. 47, the contact electrode rows CCSGa and CCSGf are disposed at positions closest to the memory hole region R_{MH} in the X-direction. The contact electrode rows CCSGc and CCSGd are disposed at positions farthest from the memory hole region R_{MH} in the X-direction. The contact electrode rows CCSGb and CCSGe are disposed between the contact electrode rows CCSGa and CCSGf and the contact electrode rows CCSGc and CCSGd in the X-direction.

In the regions R_{HU_S3} (FIG. 47), widths in the Y-direction of the conductive layers 110 (SGD) in the respective string units Sua to SUf are provided differently from widths in the Y-direction of the conductive layers 110 (SGD) in the memory hole region R_{MH}. In addition, for example, as illustrated in FIG. 47 and FIG. 49, in the regions R_{HU_S3}, the conductive layers 110 (SGD) in the respective string units SUa to SUf are disposed to have widths in the Y-direction increased at portions where the contact electrode rows CCSGa to CCSGf are disposed. The respective inter-string unit insulating layers SHE disposed between the respective string units SUa and SUf are disposed along the end portions in the Y-direction of the conductive layers 110 (SGD) and include, for example, parts extending in the X-direction and parts extending in a direction other than the X-direction.

For example, as illustrated in FIG. 49, in the parts where the contact electrode rows CCSGa to CCSGf (contact electrodes CCS) are disposed, the conductive layers 110 (SGD) have a width D30 in the Y-direction. The width D30 is greater than ⅙ of a width in the Y-direction of the memory block BLK.

For example, as illustrated in FIG. 47, insulating layers 310 are disposed between the inter-block structures ST and the regions P_In. For example, as illustrated in FIG. 50 and FIG. 51, the insulating layers 310 are disposed on parts of both side surfaces on the Y-direction side of the inter-block structures ST and extend in the X-direction and the Z-direction. The insulating layers 310 are disposed between the insulating layers 111b and the inter-block structures ST and are not disposed between the conductive layers 110 and the inter-block structures ST. The insulating layers 310 contain, for example, silicon oxide (SiO₂) or the like.

For example, as illustrated in FIG. 48, the conductive layer 110 (SGD) includes the conductive layer 110I and the conductive layer 110II. In addition, for example, as illustrated in FIG. 48, an intermediate layer 110J is disposed at a layer including the conductive layer 110I and the conductive layer 110II. The intermediate layer 110J is a layer continuously formed in a region between the contact electrodes CC and the contact electrodes CC whose positions in the X-direction are different from one another and is not electrically connected to the conductive layer 110I or the conductive layer 110II.

The conductive layers 110I, 110II and the intermediate layer 110J contain the same material.

For example, as illustrated in FIG. 48, the insulating layer 111b is disposed between the conductive layer 110I and the intermediate layer 110J.

### Manufacturing Method

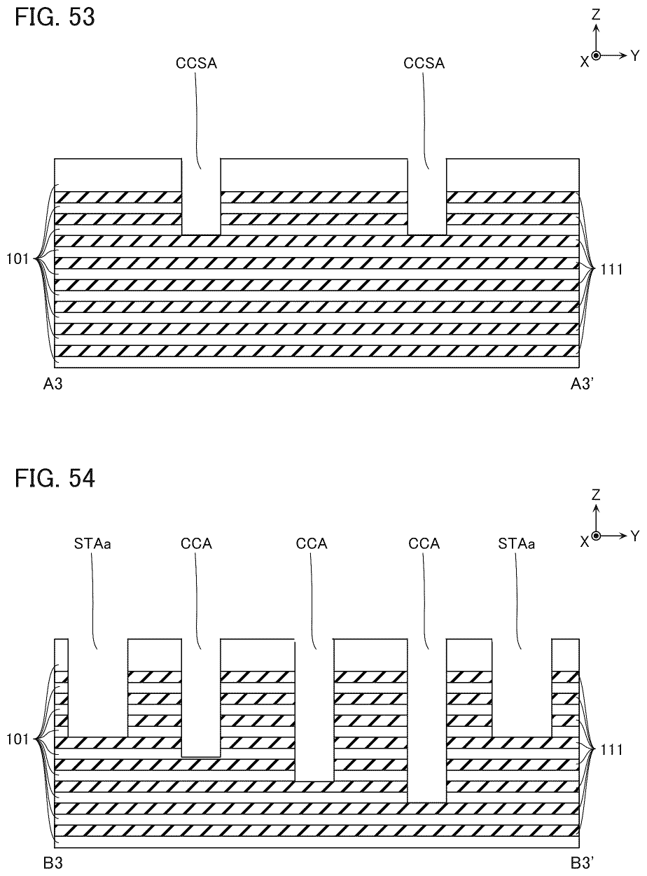

FIG. 53 to FIG. 68 are schematic cross-sectional views for describing a method for manufacturing the semiconductor memory device according to the third embodiment.

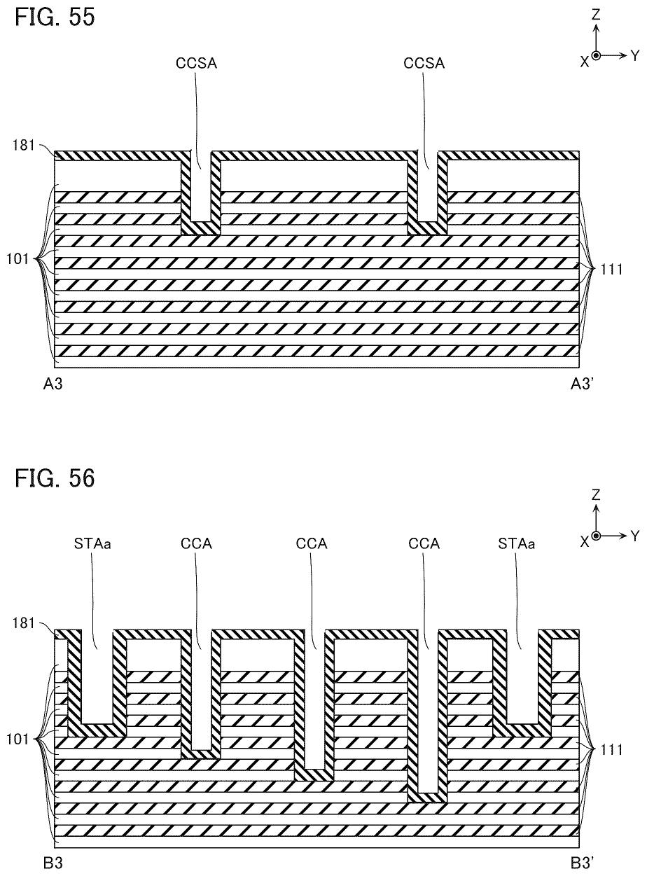

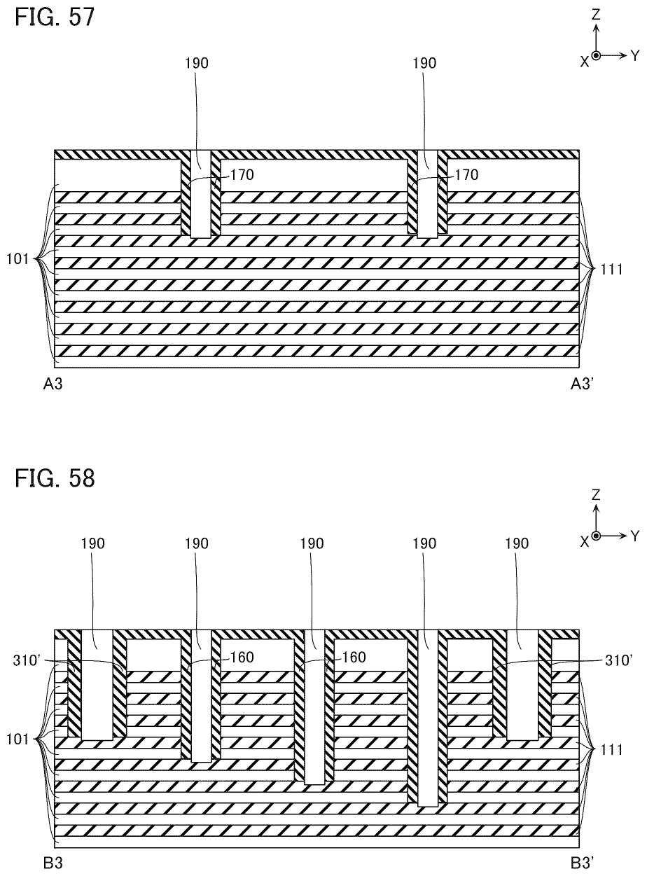

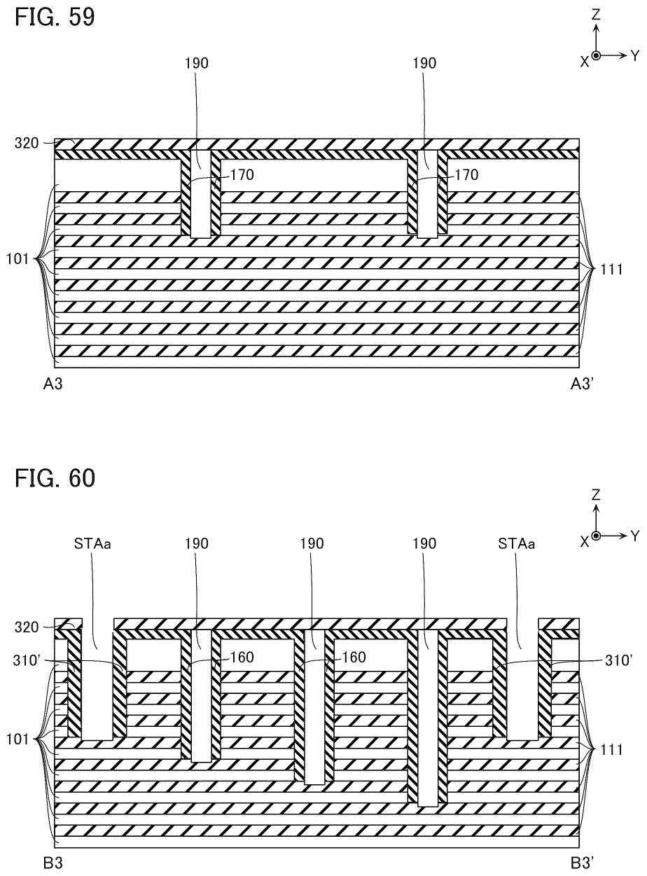

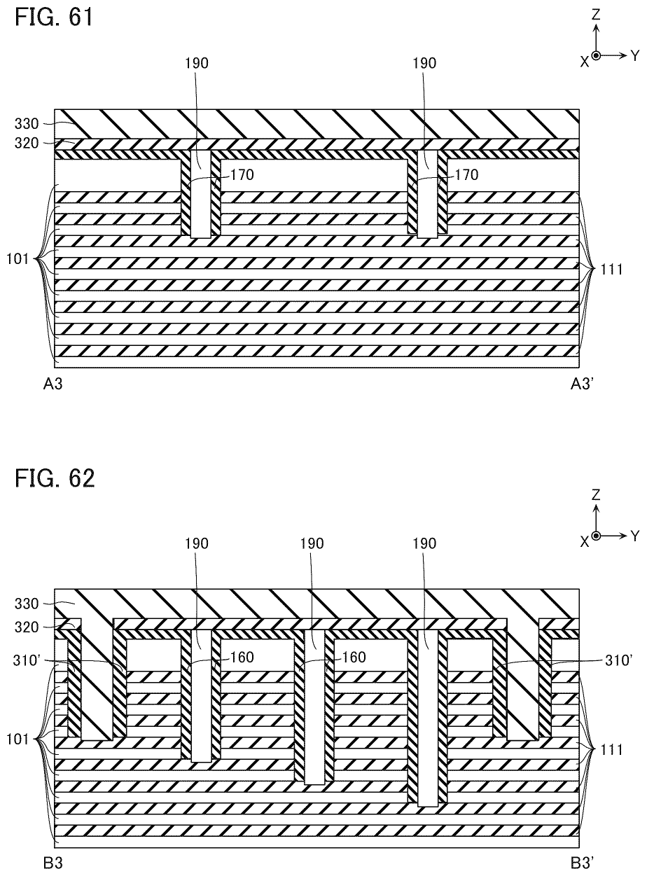

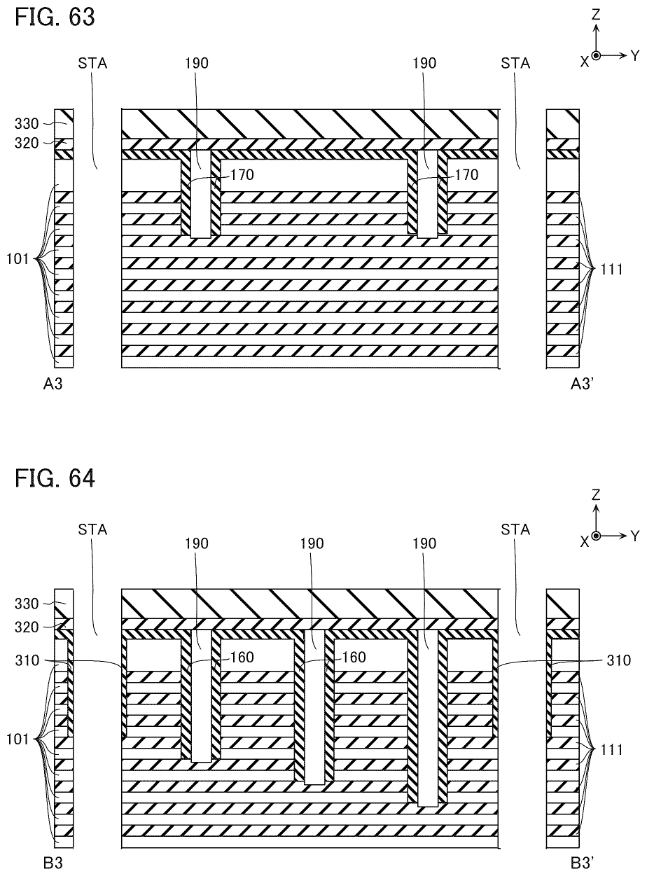

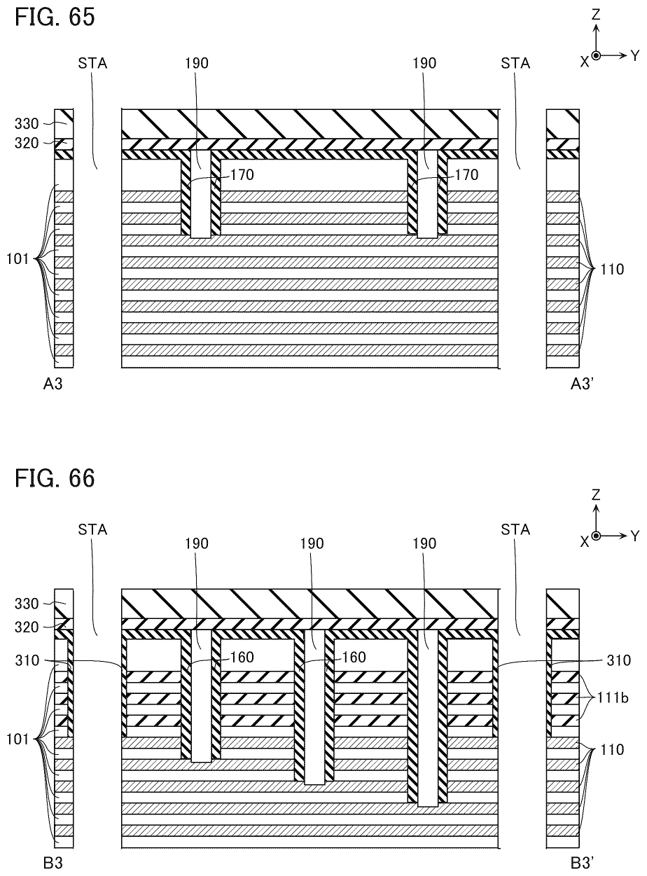

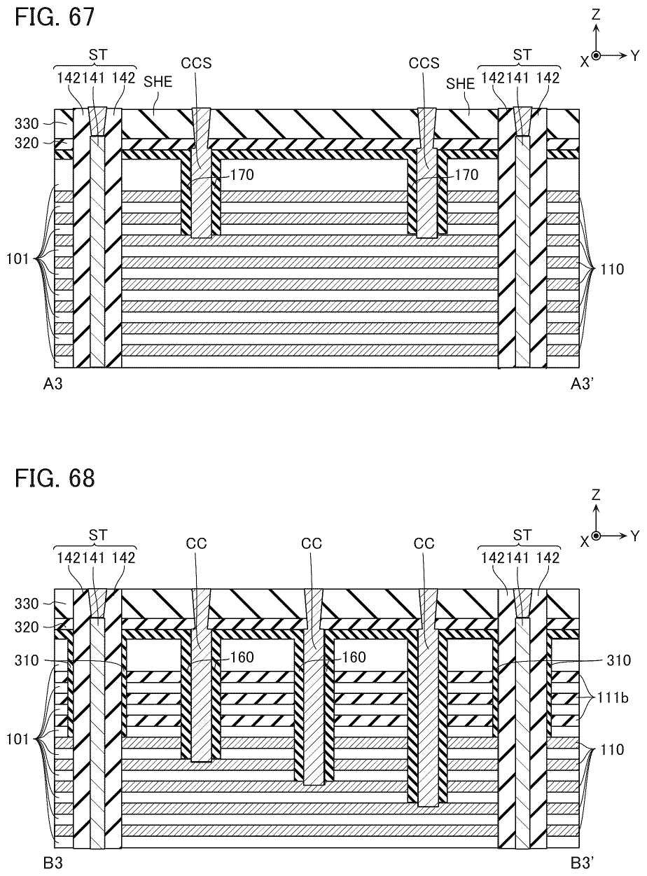

FIG. 53, FIG. 55, FIG. 57, FIG. 59, FIG. 61, FIG. 63, FIG. 65, and FIG. 67 illustrate cross-sectional surfaces corresponding to FIG. 49.

FIG. 54, FIG. 56, FIG. 58, FIG. 60, FIG. 62, FIG. 64, FIG. 66, and FIG. 68 illustrate cross-sectional surfaces corresponding to FIG. 50.

In the manufacturing method, processes similar to the processes described with reference to FIG. 9 are performed.

Next, for example, as illustrated in FIG. 53 and FIG. 54, the plurality of openings CCA, CCSA and a plurality of openings STAa are formed. The openings STAa extend in the Z-direction and penetrate a plurality of insulating layers 101 and a plurality of sacrifice layers 111 to expose a sacrifice layer 111 corresponding to the conductive layer 110 (DM). In addition, the openings STAa extend in the X-direction and are disposed between the regions P_In adjacent in the Y-direction, among portions corresponding to the inter-block structures ST. The formation of the plurality of openings CCA, CCSA, STAa is performed, for example, similarly to the process described with reference to FIG. 10.

Next, for example, as illustrated in FIG. 55 and FIG. 56, an insulating layer 181 containing a material similar to those of the insulating layers 160, the insulating layers 170, and the insulating layers 310 is formed on an upper surface of the structure illustrated in FIG. 53 and FIG. 54 and inside the openings CCA, CCSA, STAa. This process is performed by, for example, CVD or the like.

Next, for example, as illustrated in FIG. 57 and FIG. 58, parts of the insulating layer 181 at bottom portions of the openings CCA, CCSA, STAa are removed to form the insulating layers 160, 170 and insulating layers 310′ containing a material similar to that of the insulating layers 310. This process is performed by, for example, RIE or the like.

Next, for example, as illustrated in FIG. 57 and FIG. 58, the sacrifice layers 190 of amorphous silicon (α-Si) or the like are formed inside the openings CCA, CCSA, STAa. This process is performed by, for example, CVD or the like.

Next, for example, as illustrated in FIG. 59 and FIG. 60, an insulating layer 320 of silicon oxide (SiO₂) or the like is formed on an upper surface of the structure illustrated in FIG. 57 and FIG. 58. In addition, a resist and the like are formed and patterned on an upper surface of the insulating layer 320, and upper parts of portions in the insulating layer 320, which correspond to the openings STAa, are removed. Further, the sacrifice layers 190 at the portions corresponding to the openings STAa are removed to form the openings STAa. This process is performed by, for example, CVD, RIE, wet etching, or the like.

Next, for example, as illustrated in FIG. 61 and FIG. 62, an insulating layer 330 of silicon oxide (SiO₂) or the like is formed on an upper surface of the structure illustrated in FIG. 59 and FIG. 60 and inside the openings STAa. This process is performed by, for example, CVD or the like.

Next, for example, as illustrated in FIG. 63 and FIG. 64, the openings STA are formed at positions corresponding to the inter-block structures ST (FIG. 49, FIG. 50). In this process, parts of the side surfaces on the inter-block structure ST side in the Y-direction of the insulating layers 310′are removed to form the insulating layers 310. This process is performed by, for example, RIE or the like.

Next, for example, as illustrated in FIG. 65 and FIG. 66, the plurality of sacrifice layers 111 are removed by wet etching or the like via the openings STA. In this process, the plurality of sacrifice layers 111 disposed between the adjacent insulating layers 310 are not etched because they are not exposed to the openings STA and remain as the insulating layers 111b.

Next, for example, as illustrated in FIG. 65 and FIG. 66, the plurality of conductive layers 110 are formed at positions corresponding to the removed sacrifice layers 111 via the openings STA. This process is performed by, for example, CVD or the like.

Next, for example, as illustrated in FIG. 67 and FIG. 68, the inter-block structures ST are formed in the openings STA. This process is performed by, for example, CVD, RIE, or the like.

Next, for example, as illustrated in FIG. 67 and FIG. 68, parts of the insulating layers 320, 330 above the sacrifice layers 190 at positions corresponding to the contact electrodes CC, CCS are removed to form openings. After the sacrifice layers 190 are removed via these openings, the contact electrodes CC, CCS are formed. This process is performed by, for example, RIE, wet etching, CVD, or the like.

Subsequently, by forming structures above the contact electrodes CC, CCS, such as the bit lines BL, the semiconductor memory device according to the embodiment is formed.

### Effects

In the semiconductor memory device according to the embodiment, as illustrated in FIG. 48, the conductive layers 110 (SGD) contained in the respective string units SU in the regions R_{HU_S3} are electrically separated from the conductive layers 110 (SGD) in the region R_{HU_W3} by the insulating layers 111b disposed in the regions P_In. With such a configuration, the conductive layers 110 (SGD) in the regions R_{HU_S3} are not electrically conducted with one another via the conductive layers 110 (SGD) in the region R_{HU_W3}. Accordingly, the conductive layers 110 (SGD) contained in the respective string units SU in the regions R_{HU_S3} can be insulated from one another, and the string units SU can be electrically independent of one another, thus providing a semiconductor memory device that appropriately operates.

In addition, with the manufacturing method according to the embodiment, the contact electrodes CC, CCS can be simultaneously formed, therefore reducing an increase in the number of manufacturing processes and providing a semiconductor memory device manufacturable at low cost.

### Modification of Third Embodiment

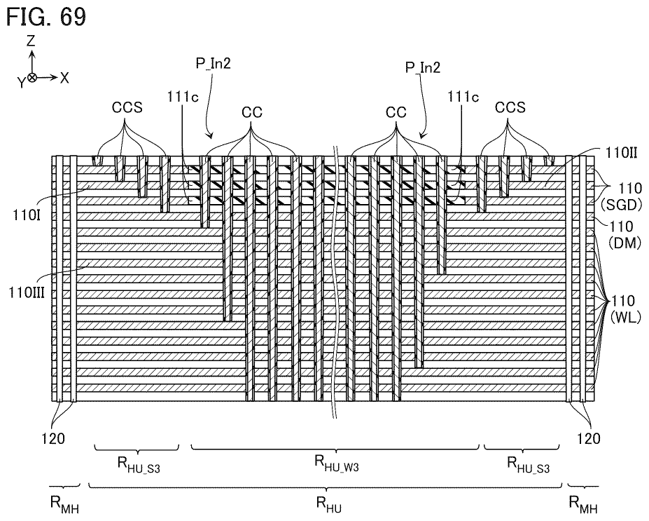

Next, with reference to FIG. 69, a modification of the semiconductor memory device according to the third embodiment is described. FIG. 69 is a schematic plan view illustrating a part of a configuration of the semiconductor memory device according to the modification.

In the semiconductor memory device according to the modification, the regions P_In (FIG. 48) are not disposed in the region R_{HU_W3}, but regions P_In2 (FIG. 69) are disposed instead.

For example, as illustrated in FIG. 69, the regions P_In2 are disposed throughout the entire regions R_{HU_W3}. For example, as illustrated in FIG. 69, in the regions P_In2, insulating layers 111c are disposed at layers disposed at the same height positions as the conductive layers 110 (SGD).

For example, as illustrated in FIG. 69, the insulating layers 111c are disposed between the conductive layers 110 (SGD) disposed in one region R_{HU_S3} and the conductive layers 110 (SGD) disposed in the other region R_{HU_S3} adjacent via the region R_{HU_W3}. The insulating layers 111c extend, for example, in the X-direction and the Y-direction. Both end portions in the Y-direction of the insulating layers 111c are in contact with the respective inter-block structures ST. The insulating layers 111c separate the conductive layers 110 (SGD) disposed in the respective regions R_{HU_S3} adjacent to one another via the region R_{HU_W3} in the X-direction to electrically separate them.

For example, as illustrated in FIG. 69, the conductive layer 110 (SGD) according to the modification includes the conductive layer 110I and the conductive layer 110II. In addition, for example, as illustrated in FIG. 69, the insulating layer 111c is disposed at a layer including the conductive layer 110I and the conductive layer 110II. The insulating layer 111c is a layer continuously formed in a region between the contact electrodes CC and the contact electrodes CC whose positions in the X-direction are different from one another and is not electrically connected to the conductive layer 110I or the conductive layer 110II. The insulating layer 111c contains, for example, a material similar to that of the sacrifice layers 111, such as silicon nitride (SiN).

### Other Embodiments

The semiconductor memory devices according to the first embodiment to the third embodiment have been described above. However, the configurations and the manufacturing methods of the semiconductor memory devices according to the first embodiment to the third embodiment are merely examples, and the specific configurations and the manufacturing methods are adjustable as appropriate.

For example, in the first embodiment to the third embodiment, one end in the Z-direction of the semiconductor layer 120 is connected to the semiconductor layer 112. However, one end in the Z-direction of the semiconductor layer 120 may be connected to the semiconductor substrate 100. In addition, for example, in the first embodiment to the third embodiment, the contact electrode CC is connected to the upper surface of a conductive layer 110. However, the contact electrode CC may be connected to a region between the upper surface and the lower surface of a conductive layer 110.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a first layer disposed to be spaced from the substrate in a first direction intersecting with a surface of the substrate;
a second layer disposed on one side in the first direction with respect to the first layer;
a third layer disposed on one side in the first direction with respect to the second layer;
a first semiconductor layer and a second semiconductor layer extending in the first direction and opposed to the first layer, the second layer, and the third layer;
a first electrode extending in the first direction and connected to the first layer;
a second electrode extending in the first direction and having an outer peripheral surface surrounded by the first layer and an end portion on one side in the first direction connected to the second layer;
a third electrode extending in the first direction and having an outer peripheral surface surrounded by the first layer and the second layer, and an end portion on one side in the first direction connected to the third layer; and
a first insulating layer extending in the first direction and a second direction intersecting with the first direction, the first insulating layer separating a part of the first layer without separating the second layer or the third layer, wherein
the second electrode and the third electrode are farther from the first semiconductor layer in the second direction than the first electrode,
the second semiconductor layer is farther from the first semiconductor layer in the second direction than the second electrode and the third electrode,
the first layer includes:
a first conductive layer opposed to the first semiconductor layer and connected to the first electrode;
a second conductive layer opposed to the second semiconductor layer; and
an intermediate layer continuously formed in a region between the second electrode and the third electrode without being electrically connected to the first conductive layer or the second conductive layer, and
each of the second layer and the third layer includes a third conductive layer that is continuously formed in a region between the first semiconductor layer and the second semiconductor layer and opposed to the first semiconductor layer and the second semiconductor layer.

2. The semiconductor memory device according to claim 1, wherein
the intermediate layer contains a same material as the first conductive layer and the second conductive layer.

3. The semiconductor memory device according to claim 1, wherein
the intermediate layer contains silicon nitride (SiN).

4. The semiconductor memory device according to claim 1, further comprising
a second insulating layer disposed between the first conductive layer and the intermediate layer and extending in a third direction intersecting with the first direction and the second direction, wherein
the second insulating layer is in contact with the first insulating layer.

5. The semiconductor memory device according to claim 4, wherein
the second insulating layer extends in the first direction and separates at least a part of the first layer without separating the second layer or the third layer.

6. The semiconductor memory device according to claim 4, further comprising
a third insulating layer and a fourth insulating layer extending in the first direction and the second direction and disposed to be in contact with one side and the other side in the third direction with respect to the first layer, the second layer, and the third layer, wherein
the second insulating layer is in contact with the third insulating layer and the fourth insulating layer.

7. The semiconductor memory device according to claim 4, further comprising
a third insulating layer and a fourth insulating layer extending in the first direction and the second direction and disposed to be in contact with one side and the other side in the third direction with respect to the first layer, the second layer, and the third layer, wherein
the second insulating layer is in contact with the third insulating layer without being in contact with the fourth insulating layer.

8. The semiconductor memory device according to claim 4, further comprising:
a fourth layer disposed between the first layer and the second layer; and
a fourth electrode extending in the first direction and having an end portion on one side in the first direction connected to the fourth layer, wherein
the first insulating layer separates a part of the fourth layer in the third direction, and
the fourth electrode is in contact with the second insulating layer.

9. The semiconductor memory device according to claim 8, wherein
at least two of the second insulating layers are disposed, and
the fourth electrode is disposed between the at least two of the second insulating layers.

10. The semiconductor memory device according to claim 1, wherein
a first electric charge accumulating film is disposed between the first conductive layer and the first semiconductor layer, and
a second electric charge accumulating film is disposed between the second conductive layer and the second semiconductor layer.

11. A semiconductor memory device comprising:
a substrate;
a first layer disposed to be spaced from the substrate in a first direction intersecting with a surface of the substrate;
a second layer disposed on one side in the first direction with respect to the first layer;
a third layer disposed on one side in the first direction with respect to the second layer;
a first semiconductor layer and a second semiconductor layer extending in the first direction and opposed to the first layer, the second layer, and the third layer;
a first electrode extending in the first direction and connected to the first layer;
a second electrode extending in the first direction and having an outer peripheral surface surrounded by the first layer and an end portion on one side in the first direction connected to the second layer;
a third electrode extending in the first direction and having an outer peripheral surface surrounded by the first layer and the second layer, and an end portion on one side in the first direction connected to the third layer; and
a first insulating layer extending in the first direction and a second direction intersecting with the first direction, the first insulating layer separating a part of the first layer without separating the second layer or the third layer, wherein
the second electrode and the third electrode are farther from the first semiconductor layer in the second direction than the first electrode,
the second semiconductor layer is farther from the first semiconductor layer in the second direction than the second electrode and the third electrode,
the first layer includes:
a first conductive layer opposed to the first semiconductor layer and connected to the first electrode; and
a second conductive layer opposed to the second semiconductor layer, and
a second insulating layer is disposed between the first conductive layer and the second conductive layer, extends in the first direction and a third direction intersecting with the first direction and the second direction, and separates the first layer without separating the second layer or the third layer.

12. The semiconductor memory device according to claim 11, wherein
the second insulating layer is in contact with the first insulating layer.

13. The semiconductor memory device according to claim 11, further comprising
a third insulating layer and a fourth insulating layer extending in the first direction and the second direction and disposed to be in contact with one side and the other side in the third direction with respect to the first layer, the second layer, and the third layer, wherein
the second insulating layer is in contact with the third insulating layer and the fourth insulating layer.

14. The semiconductor memory device according to claim 11, further comprising
a third insulating layer and a fourth insulating layer extending in the first direction and the second direction and disposed to be in contact with one side and the other side in the third direction with respect to the first layer, the second layer, and the third layer, wherein
the second insulating layer is in contact with the third insulating layer without being in contact with the fourth insulating layer.

15. The semiconductor memory device according to claim 11, further comprising:
a fourth layer disposed between the first layer and the second layer; and
a fourth electrode extending in the first direction and having an end portion on one side in the first direction connected to the fourth layer, wherein
the first insulating layer separates a part of the fourth layer in the third direction, and
the fourth electrode is in contact with the second insulating layer.

16. The semiconductor memory device according to claim 11, wherein
a first electric charge accumulating film is disposed between the first conductive layer and the first semiconductor layer, and
a second electric charge accumulating film is disposed between the second conductive layer and the second semiconductor layer.

17. A semiconductor memory device comprising:
a substrate;
a first layer disposed to be spaced from the substrate in a first direction intersecting with a surface of the substrate;
a second layer disposed on one side in the first direction with respect to the first layer;
a third layer disposed on one side in the first direction with respect to the second layer;
a first semiconductor layer and a second semiconductor layer extending in the first direction and opposed to the first layer, the second layer, and the third layer;
a first electrode extending in the first direction and connected to the first layer;
a second electrode extending in the first direction and having an outer peripheral surface surrounded by the first layer and an end portion on one side in the first direction connected to the second layer;
a third electrode extending in the first direction and having an outer peripheral surface surrounded by the first layer and the second layer, and an end portion on one side in the first direction connected to the third layer; and
a first insulating layer extending in the first direction and a second direction intersecting with the first direction, the first insulating layer separating a part of the first layer without separating the second layer or the third layer, wherein
the second electrode and the third electrode are farther from the first semiconductor layer in the second direction than the first electrode,
the second semiconductor layer is farther from the first semiconductor layer in the second direction than the second electrode and the third electrode,
the first layer includes:
a first conductive layer opposed to the first semiconductor layer and connected to the first electrode;
a second conductive layer opposed to the second semiconductor layer; and
an intermediate layer disposed between the first conductive layer and the second conductive layer and containing silicon nitride (SiN), and
the second electrode and the third electrode have outer peripheral surfaces surrounded by the intermediate layer.

18. The semiconductor memory device according to claim 17, wherein
the intermediate layer is in contact with the first insulating layer.

19. The semiconductor memory device according to claim 17, further comprising
a third insulating layer and a fourth insulating layer extending in the first direction and the second direction and disposed to be in contact with one side and the other side in a third direction with respect to the first layer, the second layer, and the third layer, the third direction intersecting with the first direction and the second direction, wherein
the intermediate layer is in contact with the third insulating layer and the fourth insulating layer.

20. The semiconductor memory device according to claim 17, wherein
a first electric charge accumulating film is disposed between the first conductive layer and the first semiconductor layer, and
a second electric charge accumulating film is disposed between the second conductive layer and the second semiconductor layer.
